(19) United States
(12) Patent Application Publication
(10) Pub. No.: US 2024/0039249 A1
(43) Pub. Date: Feb. 1, 2024

(54) LIGHT-EMITTING MODULE

(71) Applicant: NICHIA CORPORATION, Anan-shi (JP)

(72) Inventors: Kazuya HATAKEYAMA, Yokohama-shi (JP); Kazuma KOZURU, Anan-shi (JP); Masanobu TANAKA, Anan-shi (JP); Takafumi SUGIYAMA, Yoshinogawa-shi (JP)

(73) Assignee: NICHIA CORPORATION, Anan-shi (JP)

(21) Appl. No.: 18/360,268

(22) Filed: Jul. 27, 2023

(30) Foreign Application Priority Data
Jul. 29, 2022 (JP) 2022-122103

(51) Int. Cl. H01S 5/40; H01S 5/02253; H01S 5/02255

(52) U.S. Cl. CPC H01S 5/4012; H01S 5/4031; H01S 5/02253; H01S 5/02255

(57) ABSTRACT

A light-emitting module includes: a support base having a plurality of placement surfaces arranged in a first direction; a plurality of semiconductor laser elements disposed on respective ones of the plurality of placement surfaces, each semiconductor laser element configured to emit laser beams; a plurality of first mirror members, each having a first reflective surface configured to reflect and change a traveling direction of the laser beams from a respective one of the semiconductor laser elements; and a plurality of second mirror members, each having a second reflective surface, at least a portion of the second reflective surface being positioned above at least a portion of a respective one of the first reflective surfaces, and the second reflective surface being configured to reflect, in a second direction intersecting the first direction, the laser beams reflected by the respective first reflective surface.

### CROSS-REFERENCE TO RELATED APPLICATION

This application claims priority to Japanese Patent Application No. 2022-122103, filed on Jul. 29, 2022, the disclosure of which is hereby incorporated by reference in its entirety.

### BACKGROUND

The present disclosure relates to a light-emitting module.

In recent years, with an increase in output power of a semiconductor laser element, technology has been developed in which the semiconductor laser element is not used as an excitation light source but is used as a light source of a laser beam with which a material is directly irradiated to process the material. Such a technology is referred to as direct diode laser (DDL) technology.

The DDL technology uses a light-emitting module including a plurality of semiconductor laser elements. The light-emitting module combines a plurality of laser beams obtained from laser beams emitted from the plurality of semiconductor laser elements to emit a high-power laser beam. When traveling directions of the plurality of laser beams are aligned in the same direction as designed, the plurality of laser beams can be effectively combined. PCT Publication No. WO 2016/051836 discloses an example of an optical component that can reduce deviation between a traveling direction of a laser beam emitted from a semiconductor laser element and a designed traveling direction.

### SUMMARY

Provided is a light-emitting module that can effectively combine a plurality of laser beams obtained from laser beams emitted from each of a plurality of semiconductor laser elements.

A light-emitting module according to an embodiment of the present disclosure includes: a support base having a plurality of placement surfaces arranged in a first direction; a plurality of semiconductor laser elements disposed on the corresponding respective plurality of placement surfaces and each configured to emit laser beams; a plurality of first mirror members each having a first reflective surface, the first reflective surface reflecting the laser beams to change a traveling direction of the laser beams; and a plurality of second mirror members each having a second reflective surface, at least a portion of the second reflective surface being positioned above at least a portion of the first reflective surface, and the second reflective surface reflecting, in a second direction intersecting the first direction, the laser beams reflected by the first reflective surface. Positions of the second reflective surfaces of the plurality of second mirror members in the second direction are different from each other.

According to certain embodiments of the present disclosure, a light-emitting module is provided that can effectively combine a plurality of laser beams obtained from laser beams emitted from each of a plurality of semiconductor laser elements.

### BRIEF DESCRIPTION OF DRAWINGS

FIG. 1A is a top view schematically illustrating a configuration of a light-emitting module according to an exemplary first embodiment of the present disclosure.

FIG. 1B is a lateral side view schematically illustrating the configuration of the light-emitting module according to the exemplary first embodiment of the present disclosure.

FIG. 1C is another lateral side view schematically illustrating the configuration of the light-emitting module according to the exemplary first embodiment of the present disclosure.

FIG. 1D is a top view schematically illustrating a configuration of a modified example of a/the light-emitting module according to the first embodiment of the present disclosure.

FIG. 2A is a perspective view schematically illustrating an example of a configuration of a light-emitting device according to the exemplary first embodiment of the present disclosure.

FIG. 2B is a perspective view schematically illustrating another example of a configuration of the light-emitting device according to the exemplary first embodiment of the present disclosure.

FIG. 2C is an exploded perspective view of the light-emitting device illustrated in FIG. 2B.

FIG. 2D is another exploded perspective view of the light-emitting device illustrated in FIG. 2B.

FIG. 2E is a perspective view of a frame body included in the light-emitting device illustrated in FIG. 2D as viewed from below.

FIG. 2F is a top view of the configuration of the light-emitting device illustrated in FIG. 2B from which a second mirror member and a cover are omitted.

FIG. 2G is a cross-sectional view parallel to a YZ plane of the light-emitting device illustrated in FIG. 2B.

FIG. 3A is a perspective view schematically illustrating an example of a configuration of a light-emitting device according to an exemplary second embodiment of the present disclosure.

FIG. 3B is a perspective view schematically illustrating another example of the configuration of the light-emitting device according to the exemplary second embodiment of the present disclosure.

FIG. 3C is a cross-sectional view parallel to a YZ plane of the light-emitting device illustrated in FIG. 3B.

FIG. 3D is a perspective view schematically illustrating a configuration of a support included in the light-emitting device illustrated in FIG. 3A and FIG. 3B.

FIG. 4 is a view schematically illustrating a configuration of a DDL device according to an exemplary third embodiment of the present disclosure.

FIG. 5A is an exploded perspective view schematically illustrating a configuration example of a laser light source included in the light-emitting device according to the first embodiment.

FIG. 5B is a cross-sectional view parallel to the YZ plane of the laser light source illustrated in FIG. 5A.

FIG. 6A is a perspective view schematically illustrating a configuration example of a laser light source included in the light-emitting device according to the second embodiment.

FIG. 6B is a view schematically illustrating a planar configuration of an interior of the laser light source illustrated in FIG. 6A.

### DETAILED DESCRIPTIONS

A light-emitting module and a light-emitting device included in the light-emitting module according to an embodiment of the present disclosure will be described below with reference to the drawings. The same reference numerals appearing in multiple drawings indicate the same or similar parts.

The embodiment described below is provided as an example to embody the technical ideas of the present invention, and the present disclosure is not limited to the following. Further, the descriptions of dimensions, materials, shapes, relative arrangements, and the like of components are not intended to limit the scope of the present invention thereto but intended to be illustrative. The size and positional relationship of members illustrated in the drawings may be exaggerated to facilitate understanding.

In the present description and the scope of claims, polygons such as triangles or quadrangles, including shapes in which the corners of the polygons are rounded, chamfered, beveled, or coved, are referred to as polygons. A shape obtained by processing not only the corners (ends of sides), but also an intermediate portion of a side is also referred to as a polygon. In other words, a shape partially processed while leaving a polygonal shape as a base is included in the interpretation of “polygon” described in the present description and the scope of claims.

### First Embodiment

Light-emitting Module

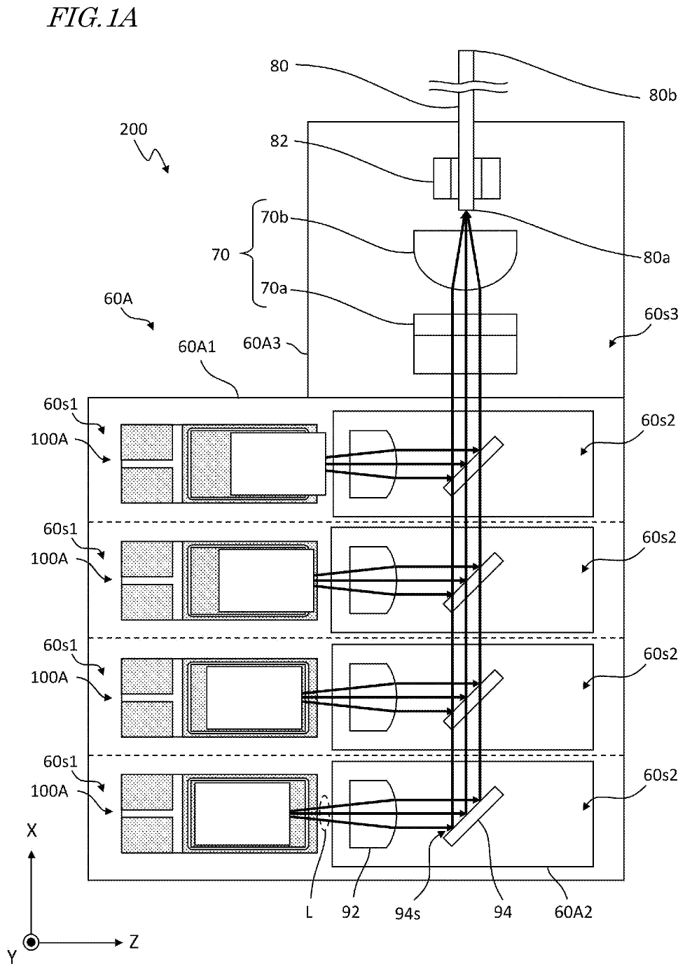

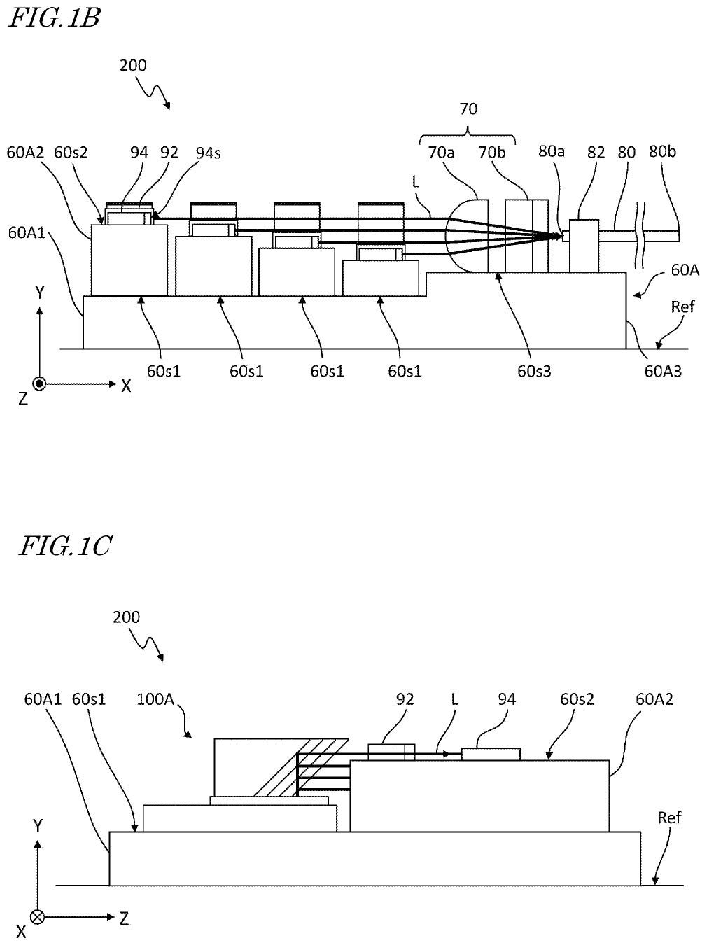

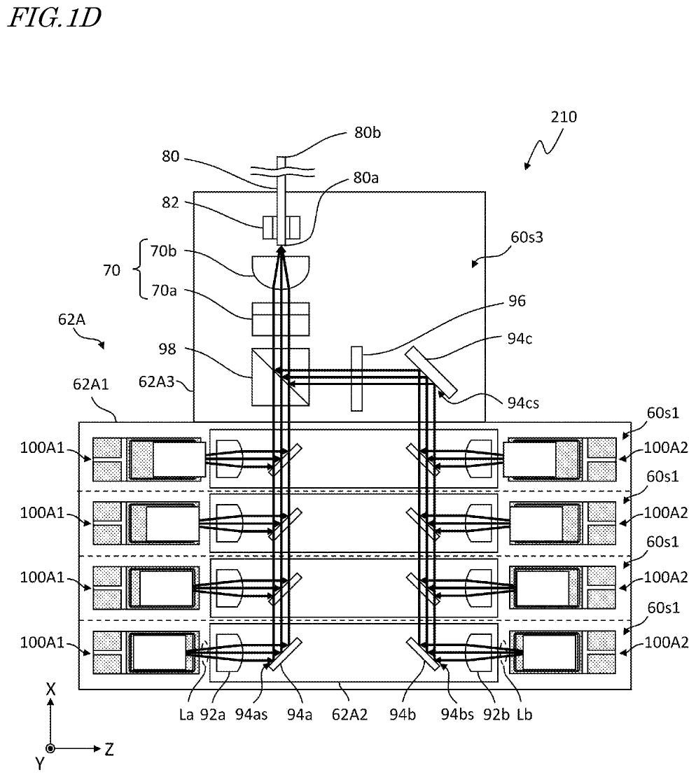

First, a configuration example of a light-emitting module according to a first embodiment of the present disclosure will be described with reference to FIG. 1A to FIG. 1C. FIG. 1A is a top view schematically illustrating a configuration of the light-emitting module according to the exemplary first embodiment of the present disclosure. FIG. 1B is a lateral side view schematically illustrating the configuration of the light-emitting module according to the exemplary first embodiment of the present disclosure. FIG. 1C is another lateral side view schematically illustrating the configuration of the light-emitting module according to the exemplary first embodiment of the present disclosure. These drawings schematically illustrate an X-axis, a Y-axis, and a Z-axis that are orthogonal to one another for reference. The direction of an arrow on the X-axis is referred to as a +X direction, and an opposite direction thereof is referred to as a −X direction. When the ±X directions are not distinguished, the ±X directions are simply referred to as X directions. The same applies to a Y direction and a Z direction. For ease of description, the present description refers to the +Y direction as “upward” and the −Y direction as “downward.” This does not limit the orientation of the light-emitting module during use, and the orientation of the light-emitting module may be any chosen orientation.

A light-emitting module 200 illustrated in FIG. 1A to FIG. 1C includes a support base 60A, a condensing lens 70, an optical fiber 80, a support member 82 that supports the optical fiber 80, a plurality of slow-axis collimating lenses 92, a plurality of mirror members 94, and a plurality of light-emitting devices 100A. Each of the mirror members 94 has a reflective surface 94s.

As illustrated in FIG. 1B, the support base 60A is disposed on a reference plane Ref parallel to an XZ plane. The reference plane Ref is a reference plane for height in the light-emitting module 200. The “height” described below is a height from the reference plane. As illustrated in FIG. 1A, the support base 60A includes a first portion 60A1 that supports the plurality of light-emitting devices 100A. The support base 60A further includes a plurality of second portions 60A2 supported by the first portion 60A1. Each of the second portions 60A2 supports the corresponding slow-axis collimating lens 92 and mirror member 94. The support base 60A further includes a third portion 60A3 connected to the first portion 60A1. The third portion 60A3 supports the condensing lens 70 and the optical fiber 80.

The first portion 60A1 includes a plurality of first placement surfaces 60s1 arranged in the X direction. The corresponding second portion 60A2 is disposed on each of the first placement surfaces 60s1. Each of the second portions 60A2 has a second placement surface 60s2. The third portion 60A3 has a third placement surface 60s3.

As illustrated in FIG. 1A, the corresponding light-emitting device 100A is disposed on each of the first placement surfaces 60s1. The corresponding slow-axis collimating lens 92 and mirror member 94 are disposed on each of the second placement surfaces 60s2. When the slow-axis collimating lens 92 and/or the mirror member 94 have a sufficiently large size in the Y direction, the slow-axis collimating lens 92 and/or the mirror member 94 may be disposed on the first placement surface 60s1 without the second portion 60A2. The condensing lens 70 is disposed on the third placement surface 60s3, and the optical fiber 80 is also disposed on the third placement surface 60s3 via the support member 82.

The following can be said from the arrangement relationship described above. Each of the light-emitting devices 100A is directly supported by the corresponding first placement surface 60s1. Each of the slow-axis collimating lenses 92 and each of the mirror members 94 are directly supported by the corresponding second placement surface 60s2. Each of the slow-axis collimating lenses 92 and each of the mirror members 94 are further indirectly supported by the corresponding first placement surface 60s1 via the corresponding second portion 60A2. The condensing lens 70 is directly supported by the third placement surface 60s3, and the optical fiber 80 is indirectly supported by the third placement surface 60s3 via the support member 82.

The plurality of first placement surfaces 60s1 is located on the same plane parallel to the XZ plane. Therefore, the heights of the plurality of first placement surfaces 60s1 are equal to each other. In contrast, the heights of the plurality of second placement surfaces 60s2 decrease stepwise along the +X direction. The height of the third placement surface 60s3 is greater than the height of the first placement surface 60s1. Furthermore, the height of the third placement surface 60s3 is less than a minimum height of the plurality of second placement surfaces 60s2. Depending on the size of the condensing lens 70 in the Y direction, the height of the third placement surface 60s3 may be equal to or may be less than the height of the first placement surface 60s1.

In the example illustrated in FIG. 1A to FIG. 1C, the quantity of the light-emitting devices 100A is four, and the quantity of the first placement surfaces 60s1 is four, but the configuration is not limited to these quantities. The quantity of the light-emitting devices 100A may be two, three, or five or more. As the quantity of the light-emitting devices 100A increases, laser beams having a higher output can be obtained. The quantity of the first placement surfaces 60s1 may be two, three, or five or more and may be equal to or greater than the quantity of the light-emitting devices 100A.

The support base 60A may be formed of ceramics selected from the group consisting of AlN, SiN, SiC, and alumina, for example. Alternatively, the support base 60A may be formed of at least one metal material selected from the group consisting of Cu, Al, and Ag, for example. The support base 60A may be formed of a metal matrix composite material containing diamond particles dispersed in at least the one metal material selected from the group consisting of Cu, Al, and Ag, for example. The support base 60A may be monolithically formed or may be an assembly of a plurality of parts. The plurality of parts may be formed of the same material as each other or may be formed of different materials from each other. For example, the first portion 60A1, the plurality of second portions 60A2, and the third portion 60A3 may be monolithically formed, or may be formed independently of each other. Alternatively, the first portion 60A1 and the third portion 60A3 may be monolithically formed, and the plurality of second portions 60A2 may be formed independently of the first portion 60A1 and the third portion 60A3.

The support base 60A is preferably formed of the metal material selected from the group consisting of Cu, Al, and Ag, and is preferably composed of a single member. The metal material has dissipation superior to ceramics and is easy to process due to its softness.

The support base 60A functions as a support base on which the plurality of light-emitting devices 100A are disposed. The support base 60A can also function as a heat sink that transfers heat generated from the plurality of light-emitting devices 100A to the outside, thus reducing an excessive temperature rise of the light-emitting devices 100A. In this case, one or a plurality of channels for liquid cooling may be provided inside the support base 60A. An example of liquid that can be used for the liquid cooling includes water. A fin structure for air cooling may be provided on the surface of the support base 60A. Alternatively, when the support base 60A is disposed on a separately prepared heat sink, the support base 60A can also function as a heat spreader that transfers the heat generated from the plurality of light-emitting devices 100A to the heat sink.

Each of the light-emitting devices 100A emits laser beams L in the +Z direction. A traveling direction of the laser beams L is parallel to the same plane on which the plurality of light-emitting devices 100A is disposed. While the plurality of light-emitting devices 100A are disposed on the same plane, heights of optical axes of the laser beams L emitted from the plurality of light-emitting devices 100A decrease stepwise along the +X direction as illustrated in FIG. 1B and FIG. 1C. A specific configuration of the light-emitting devices 100A that can make the heights of the optical axes of the laser beams L different in this manner will be described below. In the present description, the “optical axis of the laser beams” means an axis passing through the center of a far field pattern of the laser beams. The laser beams traveling along the optical axis exhibit a peak intensity in a light intensity distribution of the far field pattern.

Because the heights of the plurality of first placement surfaces 60s1 are equal to each other, variations in the amount of heat generated from the plurality of light-emitting devices 100A and transferred to the reference plane Ref can be reduced as compared with a configuration in which the heights of the plurality of first placement surfaces 60s1 are different from each other. When the first portion 60A1 includes therein a flow path extending along the X direction below the plurality of first placement surfaces 60s1, flowing a liquid into the flow path allows variations in a degree of cooling of the plurality of light-emitting devices 100A to be reduced. Therefore, the light-emitting module 200 can improve the efficiency of heat dissipation from the plurality of light-emitting devices 100A.

As illustrated in FIG. 1A, each of the slow-axis collimating lenses 92 collimates, in the XZ plane, the laser beams emitted from the corresponding light-emitting device 100A and traveling in the +Z direction. As illustrated in FIG. 1A and FIG. 1B, the reflective surface 94s of each of the mirror members 94 reflects the laser beams L emitted from the corresponding light-emitting device 100A and collimated and changes the traveling direction of the laser beams L to the +X direction toward the condensing lens 70. The laser beams L emitted from each of the light-emitting devices 100A are represented by three thick lines with arrows in the example illustrated in FIG. 1A and are represented by one thick line with an arrow in the examples illustrated in FIG. 1B and FIG. 1C. The reason for the laser beams L being represented by the three thick lines with arrows in the example illustrated in FIG. 1A is to emphasize that the laser beams L have a spread.

The condensing lens 70 includes a fast-axis condensing lens 70a and a slow-axis condensing lens 70b. The fast-axis condensing lens 70a may be a cylindrical lens having a uniform cross-sectional shape in the Z direction, for example, and the slow-axis condensing lens 70b may be a cylindrical lens having a uniform cross-sectional shape in the Y direction, for example. The respective optical axes of the fast-axis condensing lens 70a and the slow-axis condensing lens 70b are parallel to the X direction. The condensing lens 70 may be formed of at least one light-transmissive material selected from the group consisting of glass, silicon, quartz, synthetic quartz, sapphire, transparent ceramics, silicone resin, and plastic.

The fast-axis condensing lens 70a is disposed so that the focal point thereof substantially coincides with a light-incident end 80a of the optical fiber 80. Similarly, the slow-axis condensing lens 70b is disposed so that the focal point thereof substantially coincides with the light-incident end 80a of the optical fiber 80. The focal length of the fast-axis condensing lens 70a is longer than the focal length of the slow-axis condensing lens 70b. As illustrated in FIG. 1B, the fast-axis condensing lens 70a allows the plurality of laser beams L obtained from the laser beams L emitted from the plurality of light-emitting devices 100A to converge on the light-incident end 80a of the optical fiber 80 in the XY plane. As illustrated in FIG. 1A, the slow-axis condensing lens 70b allows the laser beams L having the spread and emitted from the plurality of light-emitting devices 100A to converge on the light-incident end 80a in the XZ plane.

As described above, the laser beams L emitted in the +Z direction from the plurality of light-emitting devices 100A are reflected in the +X direction by the corresponding reflective surface 94s. The plurality of laser beams L obtained in this way can be combined by the condensing lens 70 and allowed to be incident on the optical fiber 80.

As a result, the light-emitting module 200 emits the combined light, in which the plurality of laser beams L are combined, from a light-emitting end 80b of the optical fiber 80. Schematically, the output of the combined light is equal to a value obtained by multiplying the output of the laser beams L emitted from the light-emitting devices 100A by the quantity of the light-emitting devices 100. Therefore, if the quantity of the light-emitting devices 100A is increased, the output of the combined light can be increased.

Next, a modified example of the light-emitting module 200 according to a first embodiment of the present disclosure will be described with reference to FIG. 1D. FIG. 1D is a top view schematically illustrating a configuration of the modified example of the light-emitting module according to the first embodiment of the present disclosure. A light-emitting module 210 illustrated in FIG. 1D differs from the light-emitting module 200 illustrated in FIG. 1A to FIG. 1C in the following three points.

The first point is that the light-emitting module 210 includes a support base 62A instead of the support base 60A. The shape of the support base 62A is different from the shape of the support base 60A. The second point is that, in addition to a plurality of light-emitting devices 100A1, a plurality of slow-axis collimating lenses 92a, and a plurality of mirror members 94a, the light-emitting module 210 further includes a plurality of light-emitting devices 100A2, a plurality of slow-axis collimating lenses 92b, and a plurality of mirror members 94b. Each of the mirror members 94a has a reflective surface 94as, and each of the mirror members 94b has a reflective surface 94bs. The third point is that the light-emitting module 210 further includes a mirror member 94c, a half-wave plate 96, and a polarizing beam splitter 98. The mirror member 94c includes a reflective surface 94cs.

The support base 62A includes a first portion 62A1 that supports the plurality of light-emitting devices 100A1 and the plurality of light-emitting devices 100A2. The support base 62A further includes a plurality of second portions 62A2 supported by the first portion 62A1. Each of the second portions 62A2 supports the corresponding slow-axis collimating lens 92a, slow-axis collimating lens 92b, mirror member 94a, and mirror member 94b. The support base 62A further includes a third portion 62A3 connected to the first portion 62A1. The third portion 62A3 supports the condensing lens 70, the optical fiber 80, the mirror member 94c, the half-wave plate 96, and the polarizing beam splitter 98.

The first portion 62A1 has the plurality of first placement surfaces 60s1 arranged in the X direction. The corresponding second portion 62A2 is disposed on each of the first placement surfaces 60s1. Each of the second portions 62A2 has the second placement surface 60s2. The third portion 62A3 has the third placement surface 60s3. The placement surfaces 60s1 to 60s3 are as described above.

The light-emitting device 100A1, the slow-axis collimating lens 92a, and the mirror member 94a have the same configurations, respectively, as those of the light-emitting device 100A, the slow-axis collimating lens 92, and the mirror member 94 illustrated in FIG. 1A. The same applies to the light-emitting device 100A2, the slow-axis collimating lens 92b, and the mirror member 94b. The light-emitting device 100A1, the slow-axis collimating lens 92a, and the mirror member 94a are arranged in this order along the +Z direction, and the light-emitting device 100A2, the slow-axis collimating lens 92b, and the mirror member 94b are arranged in this order along the −Z direction. The light-emitting device 100A1 and the light-emitting device 100A2 are arranged in an inverted relationship with each other in the Z direction. The same applies to the arrangement of the slow-axis collimating lens 92a and the slow-axis collimating lens 92b, and to the arrangement of the mirror member 94a and the mirror member 94b.

Each of the light-emitting devices 100A1 and each of the light-emitting devices 100A2 are disposed on the corresponding first placement surface 60s1. The light-emitting devices 100A1 emit laser beams La in the +Z direction, and the light-emitting devices 100A2 emit laser beams Lb in the −Z direction. A polarization direction of the laser beams La and Lb is parallel to the X direction. Each of the slow-axis collimating lenses 92a, each of the slow-axis collimating lenses 92b, each of the mirror members 94a, and each of the mirror members 94b are disposed on the corresponding second placement surface 60s2. Each of the slow-axis collimating lenses 92a collimates, in the XZ plane, the laser beams La emitted from the corresponding light-emitting device 100A1 in the +Z direction. Each of the slow-axis collimating lenses 92b collimates, in the XZ plane, the laser beams Lb emitted from the corresponding light-emitting device 100A2 in the −Z direction. The reflective surface 94as of each of the mirror members 94a reflects the collimated laser beams La to change the traveling direction of the laser beams La to the +X direction. The reflective surface 94bs of each of the mirror members 94b reflects the collimated laser beams Lb to change the traveling direction of the laser beams Lb to the +X direction.

The mirror member 94c, the half-wave plate 96, and the polarizing beam splitter 98 are disposed on the third placement surface 60s3. The reflective surface 94cs of the mirror member 94c reflects the laser beams Lb traveling in the +X direction to change the traveling direction of the laser beams Lb to the −Z direction. The half-wave plate 96 changes the polarization direction of the laser beams Lb traveling in the −Z direction from the X direction to the Y direction. The polarizing beam splitter 98 transmits the laser beams La traveling in the +X direction and having the polarization direction in the Z direction and reflects the laser beams Lb traveling in the −Z direction and having the polarization direction in the Y direction. The laser beams La transmitted through the polarizing beam splitter 98 are converged on the light-incident end 80a of the optical fiber 80 by the condensing lens 70. Similarly, the laser beams Lb reflected by the polarizing beam splitter 98 are converged on the light-incident end 80a of the optical fiber 80 by the condensing lens 70.

As a result, the light-emitting module 210 emits the combined light in which the plurality of laser beams La and the plurality of laser beams Lb are combined, from the light-emitting end 80b of the optical fiber 80. Compared with the light-emitting module 200 illustrated in FIG. 1A, in the light-emitting module 210 illustrated in FIG. 1D, a total quantity of the light-emitting devices 100A1 and the light-emitting devices 100A2 is twice the quantity of the light-emitting devices 100. Therefore, the output of the combined light can be further increased.

In the light-emitting module 200, when the traveling directions of the plurality of laser beams L are aligned in the +X direction as designed, the plurality of laser beams L can be effectively combined by the condensing lens 70 and can be incident on the optical fiber 80. In the light-emitting module 210, the same applies when the traveling directions of the plurality of laser beams La and the plurality of laser beams Lb are aligned in the +X direction as designed.

The plurality of light-emitting devices 100A may be employed in, instead of the light-emitting module 200 according to the first embodiment and the light-emitting module 210 of the modified example thereof, a more common spatially coupling light-emitting module.

Light-Emitting Device

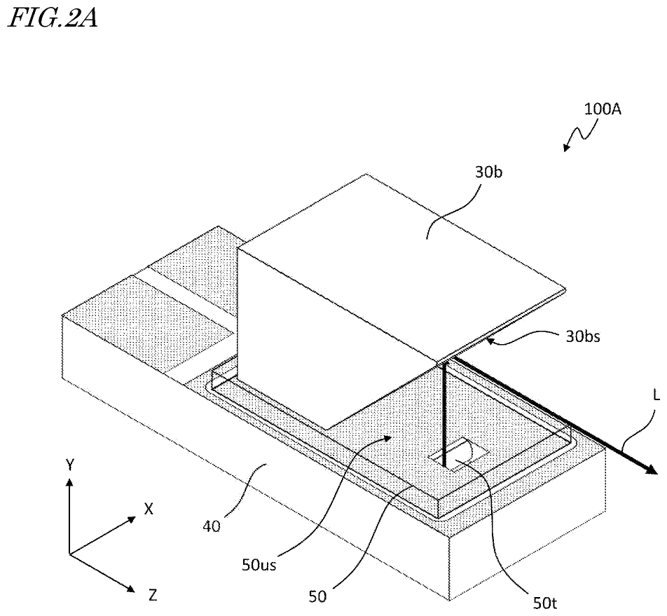

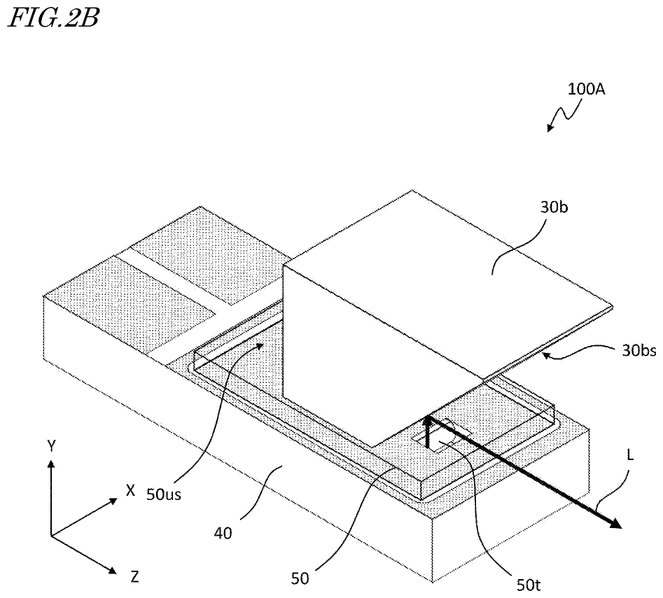

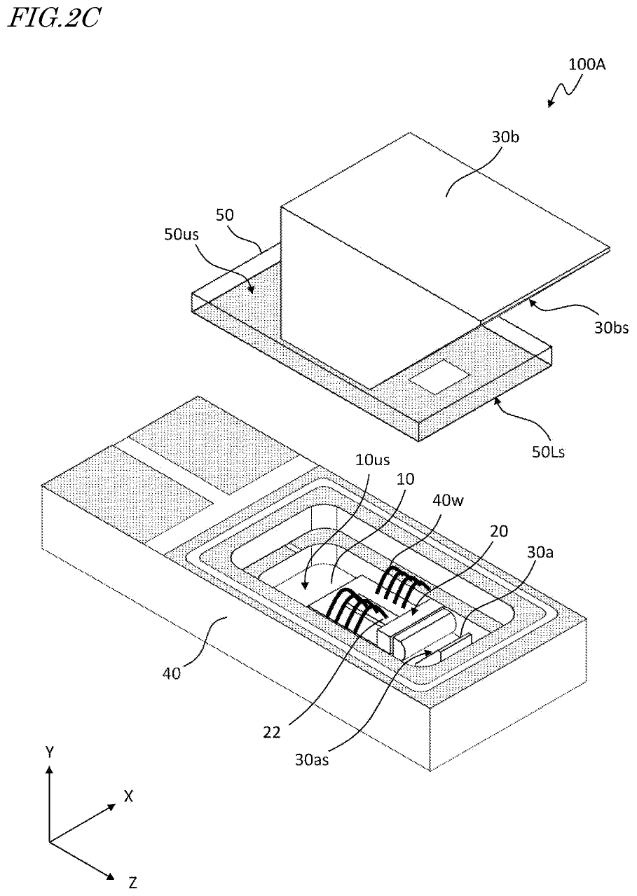

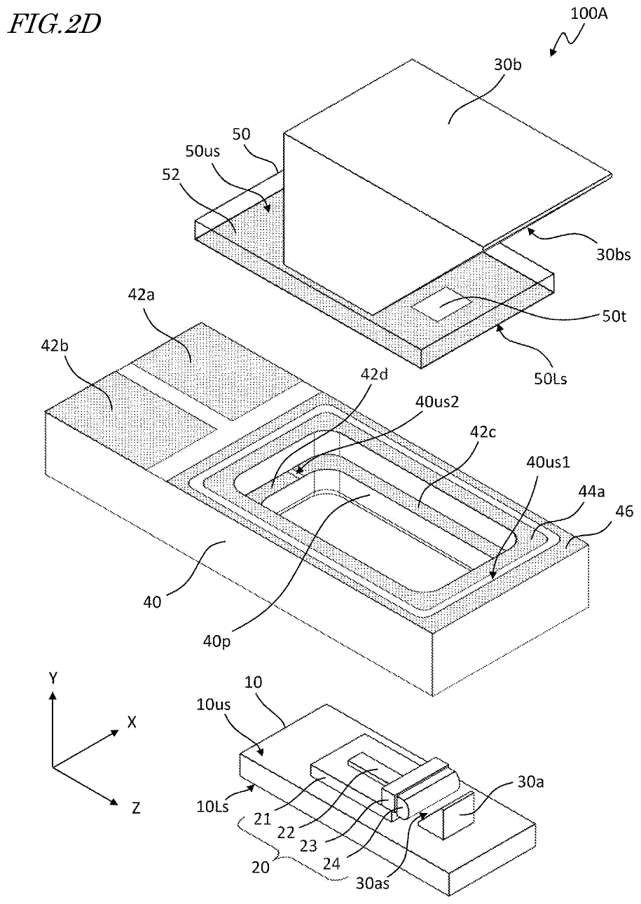

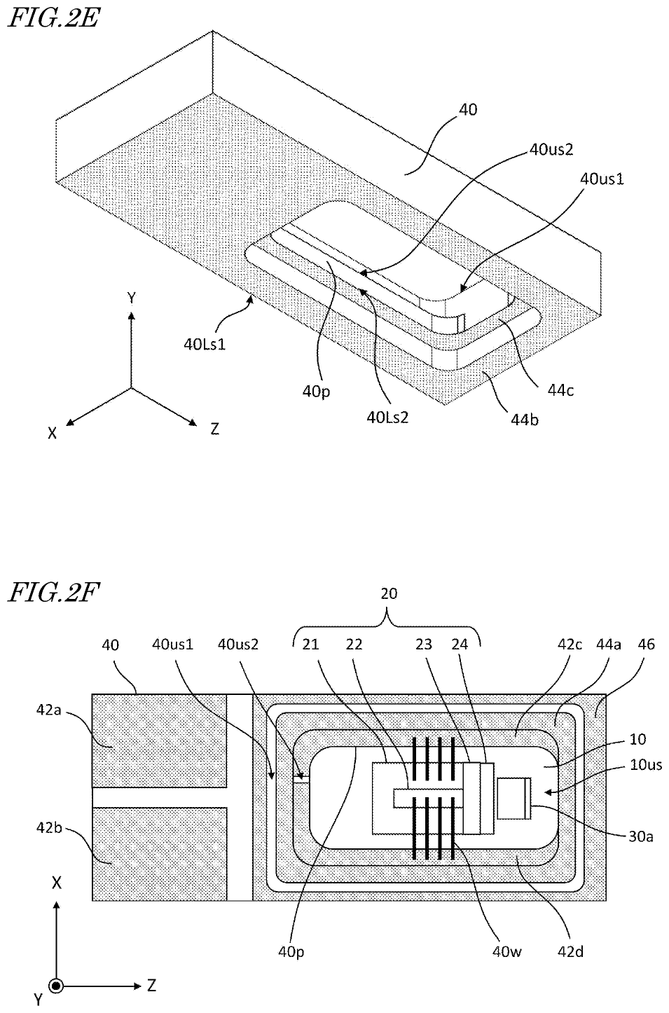

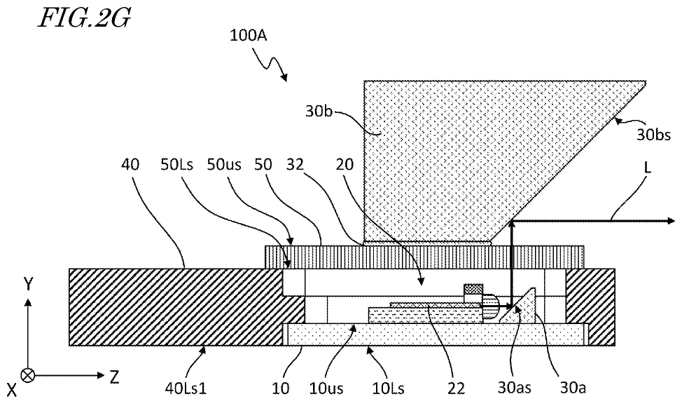

A configuration example of the light-emitting device according to the first embodiment of the present disclosure will be described below with reference to FIG. 2A to FIG. 2G. According to the light-emitting device according to the first embodiment of the present disclosure, it is possible to reduce the deviation between the traveling direction of the laser beams L and the designed traveling direction. In the present description, when the “traveling direction of the laser beams” or the like is simply denoted as the “traveling direction,” the “traveling direction” refers to an actual traveling direction.

FIG. 2A is a perspective view schematically illustrating an example of the configuration of the light-emitting device according to the exemplary first embodiment of the present disclosure. FIG. 2B is a perspective view schematically illustrating another example of the configuration of the light-emitting device according to the exemplary first embodiment of the present disclosure. The light-emitting device 100A illustrated in 2A corresponds to the light-emitting device 100A farthest from the condensing lens 70 in the X direction of the plurality of light-emitting devices 100A illustrated in FIG. 1A. The light-emitting device 100A illustrated in FIG. 2B corresponds to the light-emitting device 100A closest to the condensing lens 70 in the X direction of the plurality of light-emitting devices 100A illustrated in FIG. 1A. FIG. 2C is an exploded perspective view of the light-emitting device illustrated in FIG. 2B. The light-emitting device 100A illustrated in FIG. 2C includes a substrate 10, a laser light source 20, a first mirror member 30a, a second mirror member 30b, a frame body 40, a plurality of wires 40w, and a cover 50. The substrate 10 has a mounting surface 10us. The first mirror member 30a has a first reflective surface 30as, and the second mirror member 30b has a second reflective surface 30bs. The laser light source 20 is a chip-on-submount semiconductor laser light source including a semiconductor laser element 22. The light-emitting device 100A may further include a protective element, such as a Zener diode, and/or a temperature measuring element for measuring an internal temperature, such as a thermistor. FIG. 2D is another exploded perspective view of the light-emitting device 100A illustrated in FIG. 2B. In FIG. 2D, the plurality of wires 40w illustrated in FIG. 2C is omitted. FIG. 2E is a perspective view of the frame body 40 included in the light-emitting device 100A illustrated in FIG. 2D as viewed from below. FIG. 2F is a top view of the configuration of the light-emitting device 100A illustrated in FIG. 2B from which the second mirror member 30b and the cover 50 are omitted. FIG. 2G is a cross-sectional view parallel to a YZ plane of the light-emitting device 100A illustrated in FIG. 2B.

As will be described in detail below, in the light-emitting device 100A according to the first embodiment, the laser beams L emitted from the laser light source 20 are reflected by the first reflective surface 30as and the second reflective surface 30bs in this order, as illustrated in FIG. 2G. Such a configuration allows, regardless of whether the traveling direction of the laser beams L emitted from the laser light source 20 deviates from the +Z direction which is the designed traveling direction, the traveling direction of the laser beams L reflected by the first reflective surface 30as and the second reflective surface 30bs in this order to be directed in the +Z direction. The first reflective surface 30as reflects the laser beams L emitted from the laser light source 20 to change the traveling direction of the laser beams L to a direction away from the mounting surface 10us of the substrate 10. The second reflective surface 30bs reflects the laser beams L reflected by the first reflective surface 30as to further change the traveling direction of the laser beams L to the +Z direction.

Further, in the light-emitting device 100A according to the first embodiment, as illustrated in FIG. 2A and FIG. 2B, as the second reflective surface 30bs of the second mirror member 30b is shifted along the +Z direction, the height of the optical axis of the laser beams L reflected by the second reflective surface 30bs can be decreased. Therefore, even disposing the plurality of light-emitting devices 100A on the same plane allows the heights of the optical axes of the laser beams L emitted from the plurality of light-emitting devices 100A to be made different from each other. In the light-emitting module 200 illustrated in FIG. 1A to FIG. 1C, the positions in the +Z direction of the second reflective surfaces 30b of the plurality of second mirror members 30bs are different in the +Z direction, in a stepwise manner, along the +X direction. As a result, the heights of the optical axes of the laser beams L emitted from the plurality of light-emitting devices 100A are different, in the stepwise manner, along the +X direction.

The position and orientation of the second mirror member 30b can be adjusted so that the laser beams L reflected by the second reflective surface 30bs travel in the +Z direction. The laser beams L reflected by the second reflective surface 30bs is reflected by the reflective surface 94s as illustrated in FIG. 1A, and therefore the traveling direction of the laser beams L can be changed to the +X direction which is the designed traveling direction. As a result, it is possible to effectively combine the plurality of laser beams L traveling in the +X direction and output the high-power combined light from the light-emitting module 200.

In a configuration in which the traveling direction of the laser beams L incident on the reflective surface 94s is not parallel to the designed +Z direction, the traveling direction of the laser beams L reflected by the reflective surface 94s deviates from the designed +X direction. The plurality of laser beams L having such a deviation in the traveling direction may not be effectively combined even if the deviation is to an extent of a few degrees, and the output of the combined light may decrease.

In contrast, the first embodiment can reduce the deviation between the traveling direction of the laser beams L, which are reflected by the first reflective surface 30as and the second reflective surface 30bs in this order, and the +Z direction which is the designed traveling direction. As a result, it is possible to reduce the deviation between the traveling direction of the laser beams L reflected by the reflective surface 94s and the +X direction which is the designed traveling direction. An angle formed between the traveling direction of the laser beams L and the designed traveling direction is preferably equal to or less than 1°, and more preferably equal to or less than 0.1°, for example. In the present description, the angle formed between the two directions has a positive value and does not have a negative value.

In the first embodiment, the designed traveling direction of the laser beams L reflected by the first reflective surface 30as and the second reflective surface 30bs in this order is parallel to the +Z direction, and the designed traveling direction of the laser beams L reflected by the reflective surface 94s is parallel to the +X direction. However, the designed traveling directions are not limited to these directions.

In the present description, the direction in which the plurality of first placement surfaces 60s1 are arranged is referred to as a “first direction,” and the traveling direction of the laser beams L reflected by the first reflective surface 30as and the second reflective surface 30bs in this order is referred to as a “second direction.” The reference plane Ref is parallel to the first direction. In the first embodiment, the first direction is the +X direction, and the second direction is the +Z direction, but the directions are not limited to these examples. The second direction does not need to be orthogonal to the first direction as long as it intersects the first direction. This also applies to a second embodiment to be described below.

The light-emitting device 100A may be used for other applications without being employed in the light-emitting module 200 illustrated in FIG. 1A to FIG. 1C.

Each of components of the light-emitting device 100A will be described below.

Substrate 10

As illustrated in FIG. 2D, the substrate 10 has the mounting surface 10us and a lower surface 10Ls. The normal direction of the mounting surface 10us is the +Y direction. In the present description, the normal direction of a surface means a direction perpendicular to the surface and separating from an object having the surface. In the example illustrated in FIG. 2D, the substrate 10 has a rectangular flat plate shape, but the shape is not limited to this shape. The substrate 10 may have a circular or an elliptical flat plate shape, for example. The lower surface 10Ls of the substrate 10 is bonded to the first placement surface 60s1 of the support base 60 via an inorganic bonding member, such as a solder material.

The substrate 10 may be formed of a material having a thermal conductivity in a range from 10 W/m·K to 2000 W/m·K, for example. Due to the substrate 10 having such a high thermal conductivity, heat generated from the laser light source 20 during driving can be effectively transmitted to the support base 60A illustrated in FIG. 1A to FIG. 1C, via the substrate 10. The substrate 10 may be formed of the same material as the support base 60A, for example. The size of the substrate 10 in the X direction may be in a range from 1000 μm to 10000 μm, for example, the size in the Y direction may be in a range from 100 μm to 5000 μm, for example, and the size in the Z direction may be in a range from 1000 μm to 20000 μm, for example.

Laser Light Source 20

As illustrated in FIG. 2D, the laser light source 20 is supported by the mounting surface 10us of the substrate 10. The laser light source 20 includes a submount 21, the end-face emission type semiconductor laser element 22 supported by the submount 21, a lens support member 23, and a fast-axis collimating lens 24. The semiconductor laser element 22 is supported by the mounting surface 10us of the substrate 10 via the submount 21. The semiconductor laser element 22 is disposed so as to emit the laser beams L toward the first reflective surface 30as. The lens support member 23 has a shape straddling the semiconductor laser element 22. The fast-axis collimating lens 24 is supported by an end surface of the lens support member 23. The components of the laser light source 20 may be treated as components of the light-emitting device 100A.

The semiconductor laser element 22 emits the laser beams L from a rectangular end surface thereof. When the end surface extends in the X direction and is a plane parallel to the XY plane, the laser beams L emitted from the semiconductor laser element 22 in the +Z direction spread relatively quickly in the YZ plane and spread relatively slowly in the XZ plane. The fast axis direction of the laser beams L is parallel to the Y direction, and the slow axis direction is parallel to the X direction.

The laser light source 20 emits the laser beams emitted from the semiconductor laser element 22 and passed through the fast-axis collimating lens 24. The laser beams L emitted from the laser light source 20 are collimated in the YZ plane, but are not collimated in the XZ plane. In the present description, “collimating” refers to not only making the laser beams L parallel light but also reducing the spread angle of the laser beams L. A specific configuration of the laser light source 20 will be described below.

As illustrated in FIG. 2G, the semiconductor laser element 22 included in the laser light source 20 is sealed by the substrate 10, the frame body 40, and the cover 50. This seal is preferably a hermetic seal. The effect of the hermetic seal increases the shorter the wavelength of the laser beams emitted from the semiconductor laser element 22. This is because, in a configuration in which the emission surface of the semiconductor laser element 22 is not hermetically sealed and is in contact with the outside air, the shorter the wavelength of the laser beams is, the higher the possibility that degradation of the emission surface will progress due to dust collecting during operation.

Instead of the end-face emission type semiconductor laser element 22, a surface light emitting type semiconductor laser element, such as a vertical-cavity surface-emitting laser (VCSEL) element, may also be used. The surface light emitting type semiconductor laser element is disposed such that the laser beams emitted from the semiconductor laser element travel in the +Z direction.

First Mirror Member 30a and Second Mirror Member 30b

As illustrated in FIG. 2D, the first mirror member 30a is supported by the mounting surface 10us of the substrate 10. The first mirror member 30a has a uniform cross-sectional shape in the X direction. The cross-sectional shape is substantially triangular. The first mirror member 30a has a lower surface, a back surface, and an inclined surface connecting the lower surface and the back surface. The lower surface is parallel to the XZ plane and the back surface is parallel to the XY plane. The normal direction of the inclined surface is a direction that is parallel to the YZ plane, forms an acute angle with the +Y direction, and forms an acute angle with the −Z direction. An angle formed between the lower surface and the inclined surface of the first mirror member 30a is 45°, but is not limited to this angle, and may be in a range from 30° to 60°, for example.

The first mirror member 30a has the first reflective surface 30as on its inclined surface. The first reflective surface 30as is inclined with respect to the mounting surface 10us of the substrate 10 and faces obliquely upward. In the present description, “obliquely upward” means a direction forming an angle in a range from 30° to 60° with the +Y direction. The normal direction of the first reflective surface 30as may or does not need to be parallel to the YZ plane as long as the first reflective surface 30as can receive the laser beams L emitted from the laser light source 20 and the normal direction of the first reflective surface 30as forms the angle in the range from 30° to 60° with the +Y direction.

As illustrated in FIG. 2G, the first reflective surface 30as reflects the laser beams L emitted from the laser light source 20 to change the traveling direction of the laser beams L to the direction away from the mounting surface 10us of the substrate 10. It can also be said that the first reflective surface 30as reflects the laser beams L and changes the traveling direction of the laser beams L to a direction moving away from the first placement surfaces 60s1 illustrated in FIG. 1A to FIG. 1C. An angle between the direction in which the laser beams L travel away from the mounting surface 10us or the first placement surfaces 60s1 of the substrate 10 and the normal direction of the mounting surface 10us may be in a range from 0° to 5°, for example. Because this angle has a tolerance of 5°, it is not necessary to adjust the position and orientation of the first mirror member 30a with as much precision as the position and orientation of the second mirror member 30b.

As illustrated in FIG. 2D, the second mirror member 30b is supported by an upper surface 50us of the cover 50. The second mirror member 30b has a uniform cross-sectional shape in the X direction. The cross-sectional shape is substantially trapezoidal. The second mirror member 30b has an upper surface, a lower surface, and an inclined surface connecting the upper surface and the lower surface. Each of the upper surface and the lower surface is parallel to the XZ plane. The size of the lower surface in the X direction is equal to the size of the upper surface in the X direction. On the other hand, the size of the lower surface in the Z direction is smaller than the size of the upper surface in the Z direction. The normal direction of the inclined surface is a direction that is parallel to the YZ plane, forms an acute angle with the −Y direction, and forms an acute angle with the +Z direction. An angle formed between the upper surface and the inclined surface of the second mirror member 30b is 45°, but is not limited to this angle, and may be in a range from 30° to 60°, for example. The angle formed between the upper surface and the inclined surface of the second mirror member 30b may be equal to or different from the angle formed between the lower surface and the inclined surface of the first mirror member 30a.

The second mirror member 30b has the second reflective surface 30bs on its inclined surface. At least a portion of the second reflective surface 30bs is positioned above at least a portion of the first reflective surface 30as. As illustrated in FIG. 2G, the second reflective surface reflects the laser beams L reflected by the first reflective surface 30as to change the traveling direction of the laser beams L to the +Z direction.

A resin layer 32 is provided between the lower surface of the second mirror member 30b and the upper surface 50us of the cover 50, as illustrated in FIG. 2G. With the lower surface of the second mirror member 30b in contact with the upper surface 50us of the cover 50 via the uncured resin, the resin is cured to form the resin layer 32. The resin may be, for example, a thermosetting resin that is cured by heating, or a photocurable resin that is cured by irradiation with ultraviolet rays or visible light. Before the resin is cured, the following active alignment is performed. That is, the position and the orientation of the second mirror member are appropriately adjusted so that the second reflective surface 30b changes the traveling direction of the laser beams L to the +Z direction with the laser light source 20 emitting the laser beams L. Such an adjustment may be performed while holding the second mirror member 30b using a holding device, after the light-emitting device 100A is disposed on the first placement surface 60s1 of the support base 60A illustrated in FIG. 1A to FIG. 1C.

The traveling direction of the laser beams L can be adjusted by rotating the second mirror member 30b about the X-axis or the Y-axis as a rotation axis, to change the orientation thereof. Rotating the second mirror member 30b about the X-axis as the rotation axis can change the traveling direction of the laser beams L up and down. Rotating the second mirror member 30b about the Y-axis as the rotation axis can change the traveling direction of the laser beams L right and left, with the traveling direction of the laser beams L being the front direction.

Furthermore, the height of the optical axis of the laser beams L can be adjusted by changing the position of the second reflective surface 30bs of the second mirror member 30b in the Z direction. The height of the optical axis of the laser beams L can be reduced by shifting the second reflective surface 30bs of the second mirror member 30b along the +Z direction, and the height of the optical axis of the laser beams L can be increased by shifting the second mirror member 30b along the −Z direction.

The greater a size from the upper edge to the lower edge of the second reflective surface 30bs, the more widely the range over which the height of the optical axis of the laser beams L reflected by the second reflective surface 30bs can be adjusted. In the example illustrated in FIG. 1B, the upper edge of the second reflective surface 30bs is located higher than a position at which the optical axis of the laser beams L hits the reflective surface 94s of the mirror member 94 farthest from the condensing lens 70 in the X direction. The lower edge of the second reflective surface 30bs is located lower than a position at which the optical axis of the laser beams L hits the reflective surface 94s of the mirror member 94 closest to the condensing lens 70 in the X direction.

When the size from the upper edge to the lower edge of the second reflective surface 30bs is large, the lower surface of the second mirror member 30b is widened accordingly, and the second mirror member 30b can thus be stably disposed on the upper surface 50us of the cover 50. The size of the lower surface of the second mirror member 30b in the X direction can be, for example, in a range from 0.8 times to 1.2 times the size of the upper surface 50us of the cover 50 in the X direction. The size of the lower surface of the second mirror member 30b in the Z direction can be, for example, in a range from 0.3 times to 0.8 times the size of the upper surface 50us of the cover 50 in the Z direction. Because the second mirror member 30b having such a large size is easily held by the holding device, it is easy to arrange the second mirror member 30b in an appropriate position and orientation.

The exterior appearance of the plurality of second mirror members 30b may have the same shape, but the plurality of second reflective surfaces 30bs may be disposed at different positions from each other. In this case, the second reflective surface 30bs may be positioned in the interior of the second mirror member 30b, and a portion of the second mirror member 30b positioned further to the front than the second reflective surface 30bs may be transmissive with respect to the laser beams L. Such a plurality of second mirror members 30b allows, even if the plurality of second mirror members 30b is disposed at the same position in the +Z direction along the +X direction, the plurality of second reflective surfaces 30bs to be shifted in the +Z direction in the stepwise manner along the +X direction.

Here, in contrast to the first embodiment, a configuration in which the second mirror member 30b is fixed to the upper surface 50us of the cover 50 without adjusting the position and orientation thereof will be described as an example. Even with such a configuration, by disposing a wedge between the second mirror member 30b and the slow-axis collimating lens 92 in the light-emitting module 200 illustrated in FIG. 1A to FIG. 1C, the traveling direction of the laser beams L reflected by the second reflective surface 30bs can be directed to the +Z direction. The wedge has a light incident surface and a light reflective surface positioned on sides opposite to each other. The normal direction of the light incident surface is parallel to the −Z direction. The normal direction of a light-emitting surface is parallel to the YZ plane, forms an acute angle with the +Y direction or the −Y direction, and forms an acute angle with the +Z direction. Due to the light incident surface and the refraction at the light incident surface which are not parallel to each other, the wedge can change the traveling direction of the laser beams L transmitted through the wedge. However, when using the wedge, to direct the traveling direction of the laser beams L to the +Z direction, it is necessary to prepare a plurality of the wedges for which the normal directions of the light-emitting surfaces are mutually different to select the wedge having the appropriate normal direction of the light-emitting surface from among the plurality of wedges.

In contrast, in the first embodiment, disposing the second mirror member 30b in an appropriate position and orientation allows the traveling direction of the laser beams L reflected by the second reflective surface 30bs to be directed to the +Z direction, regardless of whether the traveling direction of the laser beams L emitted from the laser light source 20 is deviated from the +Z direction. In the first embodiment, it is not necessary to prepare a plurality of the second mirror members 30b having mutually different angles formed between the upper surface and the inclined surface and to select the second mirror member 30b having the appropriate angle from among the plurality of second mirror members 30b.

In the present description, the mirror member 94 illustrated in FIG. 1A to FIG. 1C is also referred to as a “third mirror member,” and the reflective surface 94s illustrated in FIG. 1A to FIG. 1C is also referred to as a “third reflective surface.” The third reflective surface 94s reflects, in the +X direction, the laser beams reflected by the second reflective surface 30bs.

The mirror members 30a and 30b illustrated in FIG. 2C and FIG. 2D, the mirror member 94 illustrated in FIG. 1A to FIG. 1C, and the mirror members 94a to 94c illustrated in FIG. 1D may, for example, include a base having an inclined surface and a reflective surface as an individual member formed on the inclined surface. The base may be formed of at least one material selected from the group consisting of glass, quartz, synthetic quartz, sapphire, ceramics, plastic, silicon, metal, silicone resin, and a dielectric material, for example. The reflective surface may be formed from a reflective material, such as a dielectric multilayer film and a metal material, for example. This reflective surface corresponds to the reflective surface 30as and the reflective surface 30bs illustrated in FIG. 2C, to the reflective surface 94s illustrated in FIG. 1A, and to the reflective surfaces 94as to 94cs illustrated in FIG. 1D.

Alternatively, the first mirror member 30a, the second mirror member 30b, the mirror member 94, and the mirror members 94a to 94c may include a base having an inclined surface, for example, and the base may be formed of the above-described reflective material. In this case, the inclined surface of the base corresponds to the first reflective surface 30as, to the second reflective surface 30bs, to the reflective surface 94s, and to the reflective surfaces 94as to 94cs.

Frame Body 40

The frame body 40 is positioned around the mounting surface 10us of the substrate 10, as illustrated in FIG. 2C, and supports the cover 50 as illustrated in FIG. 2B. As illustrated in FIG. 2C, the frame body 40 surrounds the laser light source 20 and the first mirror member 30a when seen along the +Y direction, that is, in a top view. As illustrated in FIG. 2D, the frame body 40 includes a protruding portion 40p protruding inward from the inner surface. In the example illustrated in FIG. 2F, the protruding portion 40p protrudes toward both lateral surfaces and the back surface of the submount 21. The protruding portion 40p may further protrude toward the front surface of the submount 21. Further, the protruding portion 40p may protrude only to both the lateral surfaces. The front surface of the submount 21 is positioned on the same side as the emission surface of the semiconductor laser element 22, and the back surface of the submount 21 is positioned on the side opposite to the emission surface of the semiconductor laser element 22. Both the lateral surfaces of the submount 21 connect the front surface and the back surface of the sub-mount 21.

As illustrated in FIG. 2D, the frame body 40 has a first upper surface 40us1 and a second upper surface 40 us2. The second upper surface 40 us2 is an upper surface of the protruding portion 40p, is positioned lower than the first upper surface 40us1, and is surrounded by the first upper surface 40us1 in a top view. As illustrated in FIG. 2F, the second upper surface 40us2 has a substantial U-shape.

The first upper surface 40us1 includes a first bonding region 44a and an outer region 46 surrounding the first bonding region 44a. Each of the first bonding region 44a and the outer region 46 has a substantially rectangular annular shape. The first bonding region 44a improves a bonding strength when the cover 50 and the frame body 40 are bonded to each other via an inorganic bonding member, such as a solder material. The outer region 46 reduces the inorganic bonding member that bonds the cover 50 flowing out beyond the outer region 46. As illustrated in FIG. 2F, the first bonding region 44a and the outer region 46 surround the laser light source 20 and the first mirror member 30a in a top view. A first conductive region 42a and a second conductive region 42b, which are electrically insulated from each other, are further provided on the first upper surface 40us1, at a position extended in the −Z direction from the first bonding region 44a and the outer region 46.

A third conductive region 42c and a fourth conductive region 42d, which are electrically insulated from each other, are provided on the second upper surface 40 us2. The third conductive region 42c is electrically connected to the first conductive region 42a via internal wiring, and the fourth conductive region 42d is electrically connected to the second conductive region 42b via internal wiring. As illustrated in FIG. 2F, in a top view, the laser light source 20 and the first mirror member 30a are positioned between a portion of the third conductive region 42c extending in the Z direction and a portion of the fourth conductive region 42d extending in the Z direction. The third conductive region 42c is electrically connected to the semiconductor laser element 22 via the upper surface of the submount 21 and one or more the wires 40w illustrated in FIG. 2C. The fourth conductive region 42d is electrically connected to the semiconductor laser element 22 via the remaining wires 40w illustrated in FIG. 2C. Therefore, by applying a voltage between the first conductive region 42a and the second conductive region 42b, power can be supplied to the laser light source 20. As illustrated in FIG. 2E, the frame body 40 further includes a first lower surface 40Ls1 and a second lower surface 40Ls2. The second lower surface 40Ls2 partially has the lower surface of the protruding portion 40p, is positioned higher than the first lower surface 40Ls1, and is surrounded by the first lower surface 40Ls1 when seen along the −Y direction, that is, in a bottom view. The second lower surface 40Ls2 has a substantially rectangular annular shape. A part or all of the substrate 10 illustrated in FIG. 2D is accommodated in a space surrounded by a step between the first lower surface 40Ls1 and the second lower surface 40Ls2. When viewed through the frame body 40, the outer periphery of the second lower surface 40Ls2 surrounds the outer periphery of the mounting surface 10us of the substrate 10 in a top view, and the inner periphery of the second lower surface 40Ls2 is surrounded by the outer periphery of the mounting surface 10us of the substrate 10 in a top view.

A second bonding region 44b is provided over the entire first lower surface 40Ls1. The second bonding region 44b improves a bonding strength when the support base 60A and the frame body 40 illustrated in FIG. 1A to FIG. 1C are bonded to each other via an inorganic bonding member, such as a solder material. A third bonding region 44c is provided over the entire second lower surface 40Ls2. The third bonding region 44c is bonded to a peripheral edge region of the mounting surface 10us of the substrate 10 via an inorganic bonding member, such as a brazing material. The third bonding region 44c improves a bonding strength when the substrate 10 and the frame body 40 are bonded via the inorganic bonding member. The melting point of the brazing material is higher than the melting point of the solder material. Therefore, when the brazing material is heated to bond the substrate 10 and the frame body 40, and subsequently the solder material is heated to bond the substrate 10 and the laser light source 20, it is possible to reduce the possibility that the bonding of the substrate 10 and the frame body 40 may come off as a result of the heat applied to the solder material.

In the example illustrated in FIG. 2E, the second bonding region 44b is provided over the entire first lower surface 40Ls1, but the second bonding region 44b may be provided on a part of the first lower surface 40Ls1. Similarly, in the example illustrated in FIG. 2E, the third bonding region 44c is provided over the entire second lower surface 40Ls2, but the third bonding region 44c may be provided on a part of the second lower surface 40Ls2. Further, the second bonding region 44b does not need to be provided on the first lower surface 40Ls1, and the third bonding region 44c does not need to be provided on the second lower surface 40Ls2. When the second bonding region 44b is not provided on the first lower surface 40Ls1, the substrate 10 and the support base 60A are bonded only at the lower surface 10Ls of the substrate 10, without bonding the frame body 40 and the support base 60A.

In the example illustrated in FIG. 2G, the first lower surface 40Ls1 of the frame body 40 is positioned on the same plane as the lower surface 10Ls of the substrate 10. The first lower surface 40Ls1 of the frame body 40 may be positioned higher than the lower surface 10Ls of the substrate 10. Alternatively, the first lower surface 40Ls1 of the frame body 40 may be positioned lower than the lower surface 10Ls of the substrate 10, if the first lower surface 40Ls1 does not cause obstruction when bonding the substrate 10 and the support base 60A via the inorganic bonding member.

Similar to, for example, the support base 60A illustrated in FIG. 1A to FIG. 1C, the frame body 40 may be formed of the above-described ceramics. The size of the frame body 40 in the X direction may be in a range from 3 mm to 15 mm, for example, the maximum size thereof in the Y direction may be in a range from 1 mm to 5 mm, for example, and the size thereof in the Z direction may be in a range from 3 mm to 30 mm, for example.

The conductive regions 42a to 42d, the bonding regions 44a to 44c, and the outer region 46 may be formed of at least one metal material selected from the group consisting of Ag, Cu, W, Au, Ni, Pt, and Pd, for example. The conductive regions 42a to 42d, the bonding region 44a, and the outer region 46 can be formed, for example, by providing a metal film over the entire upper surfaces 40us1 and 40us2 and patterning the metal film by etching.

Cover 50

As illustrated in FIG. 2C, the cover 50 has an upper surface 50us and a lower surface 50Ls. The lower surface 50Ls of the cover 50 faces the mounting surface 10us of the substrate 10, and the upper surface 50us of the cover 50 is positioned on the side opposite to the lower surface 50Ls of the cover 50. In the present description, the lower surface 50Ls of the cover 50 is also referred to as a “facing surface.” The cover 50 is positioned above the semiconductor laser element 22 and the first mirror member 30a. The cover 50 transmits the laser beams L reflected by the first reflective surface 30as.

The cover 50 includes a light-shielding film 52 on a portion of the lower surface 50Ls where is positioned at least a portion around a light-transmitting region 50t through which the laser beams L are transmitted. In the example illustrated in FIG. 2D, the light-transmitting region 50t has a rectangular shape, but the shape is not limited to this shape. The shape of the light-transmitting region 50t may be, for example, a circular shape or an elliptical shape. Alternatively, the cover 50 may include, on the lower surface 50Ls, the light-shielding film 52 on a part at least around the light-transmitting region 50t. For example, when a part of an end of the light-transmitting region 50t coincides with a part of an end of the lower surface 50Ls, the light-shielding film 52 may be provided on at least a part of a region described below on the lower surface 50Ls. This region is a region of the lower surface 50Ls where is adjacent to the remaining part other than the above-described part of the end of the light-transmitting region 50t.

The light-shielding film 52 reduces the possibility of stray light other than the laser beams L generated inside the light-emitting device 100A leaking to the outside of the light-emitting device 100A. The light-shielding film 52 further reduces the possibility of ultraviolet rays or visible light reaching the laser light source 20 when the resin layer 32 illustrated in FIG. 2G is formed by the irradiation of the ultraviolet rays or visible light. The light-shielding film 52 further reduces the possibility that return light of the laser beams L emitted to the outside of the light-emitting device 100A may reach the laser light source 20. If irradiation by the ultraviolet rays, the visible light, or the return light can be reduced, the laser light source 20 is less likely to be damaged.

In the example illustrated in FIG. 2D, the light-shielding film 52 is provided over the entire region other than the light-transmitting region 50t on the lower surface 50Ls. The light-shielding film 52 provided in such a manner further reduces the possibility of the stray light leaking to the outside of the light-emitting device 100A, and the possibility of the above-described ultraviolet rays, the visible light, or the return light reaching the laser light source 20.

The laser beams L are transmitted not only through the light-transmitting region 50t but also through a part of the cover 50 that overlaps the light-transmitting region 50t in a top view. The part of the cover 50 that transmits the laser beams L may have a transmittance of the laser beams L equal to or greater than 60%, for example, and preferably has a transmittance of the laser beams L equal to or greater than 80%. The remaining part of the cover 50 may or does not need to have such light-transmissive properties.

Similar to, for example, the condensing lens 70 illustrated in FIG. 1A and FIG. 1B, the cover 50 may be formed of the above-described light-transmissive material. The size of the cover 50 in the X direction may be in a range from 3 mm to 15 mm, for example, the size thereof in the Y direction may be in a range from 0.1 mm to 1.5 mm, for example, and the size thereof in the Z direction may be in a range from 1 mm to 20 mm, for example.

Similar to, for example, the conductive regions 42a to 42d, the bonding regions 44a to 44c, and the outer region 46, the light-shielding film 52 may be formed of the above-described metal material. Similar to, for example, the conductive regions 42a to 42d, the bonding region 44a, and the outer region 46, the light-shielding film 52 may be formed by providing a metal film over the entire lower surface 50Ls of the cover 50 and patterning the metal film by etching.

The peripheral region of the light-shielding film 52 is bonded to the first bonding region 44a provided on the first upper surface 40us1 of the frame body 40, via an inorganic bonding member such as a solder material. When the light-shielding film 52 is formed of the above-described metal material, the light-shielding film 52 improves the bonding strength when the cover 50 and the frame body 40 are bonded to each other via the inorganic bonding member.

In the example illustrated in FIG. 2A to FIG. 2G, the cover 50 has a flat plate shape, but the shape is not limited to this shape. In a configuration in which the substrate 10 has a flat plate shape without the frame body 40 provided, the cover 50 may have a box shape with an open lower portion instead of the flat plate shape. The cover 50 having such a shape is supported by the mounting surface 10us of the substrate 10 and accommodates the laser light source 20 and the first mirror member 30a. Further, a configuration may be adopted in which the cover 50 having the box shape with the open lower portion is bonded to the frame body 40, and the laser light source 20 and the first mirror member 30a may be surrounded by the cover 50 and the frame body 40.

As described above, the first embodiment provides the light-emitting device 100A that can reduce the deviation between the traveling direction of the laser beams L and the designed traveling direction. Furthermore, even disposing the plurality of light-emitting devices 100A on the same plane allows the heights of the optical axes of the laser beams L emitted from the plurality of light-emitting devices 100A to be made different from each other by making the positions of the second reflective surfaces 30bs of the plurality of second mirror members 30b in the Z direction different from each other. The height of an intersection point of the second reflective surface 30bs and the optical axis of the laser beams L with respect to the same plane described above differs depending on the position of the second reflective surface of the plurality of second mirror members 30bs in the +Z direction. Employing such a light-emitting device 100A in the light-emitting module 200 illustrated in FIG. 1A to FIG. 1C allows the plurality of laser beams L obtained from the laser beams L emitted from each of the plurality of light-emitting devices 100A to be effectively combined and caused to be incident on the optical fiber 80.

In the light-emitting module 200, the two or more light-emitting devices 100A are dispose on the same plane along the X direction. On the other hand, the number of light-emitting devices 100A may be increased by disposing the two or more light-emitting devices 100A on each of a plurality of planes having different heights and arranged along the X direction.

The light-emitting device 100A may be manufactured in the following manner, for example. In an initial step, the substrate 10, the laser light source 20, the first mirror member 30a, the second mirror member 30b, the frame body 40, the plurality of wires 40w, and the cover 50 are prepared. In a subsequent step, the frame body 40 is bonded to the substrate 10. In a subsequent step, the laser light source 20 and the first mirror member 30a are provided on the mounting surface 10us of the substrate 10. In a subsequent step, the plurality of wires 40w for supplying the power to the laser light source 20 is provided. In a subsequent step, the cover 50 is bonded to the frame body 40. In a subsequent step, active alignment is performed with the lower surface of the second mirror member 30b in contact with the upper surface 50us of the cover 50 via the uncured resin. In a subsequent step, the resin is cured and the resin layer 32 is formed between the second mirror member 30b and the cover 50.

### Second Embodiment

In the light-emitting device 100A according to the first embodiment, the semiconductor laser element 22 is sealed by the substrate 10, the frame body 40, and the cover 50, the first mirror member 30a is positioned inside the space in which the semiconductor laser element 22 is sealed, and the second mirror member 30b is positioned outside the space. However, the first mirror member 30a does not need to be positioned inside the space.

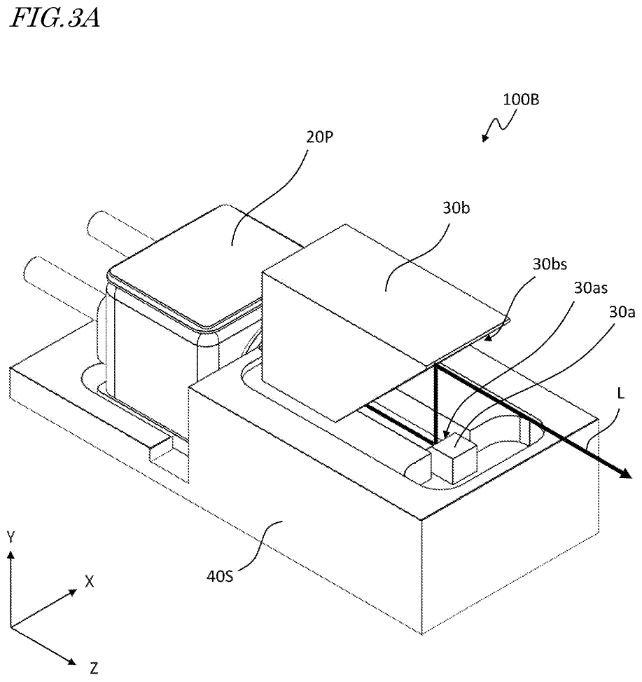

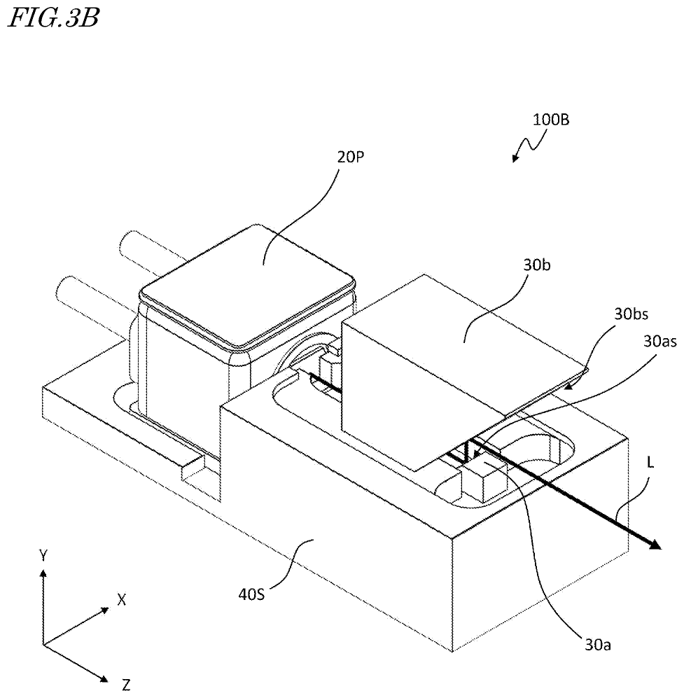

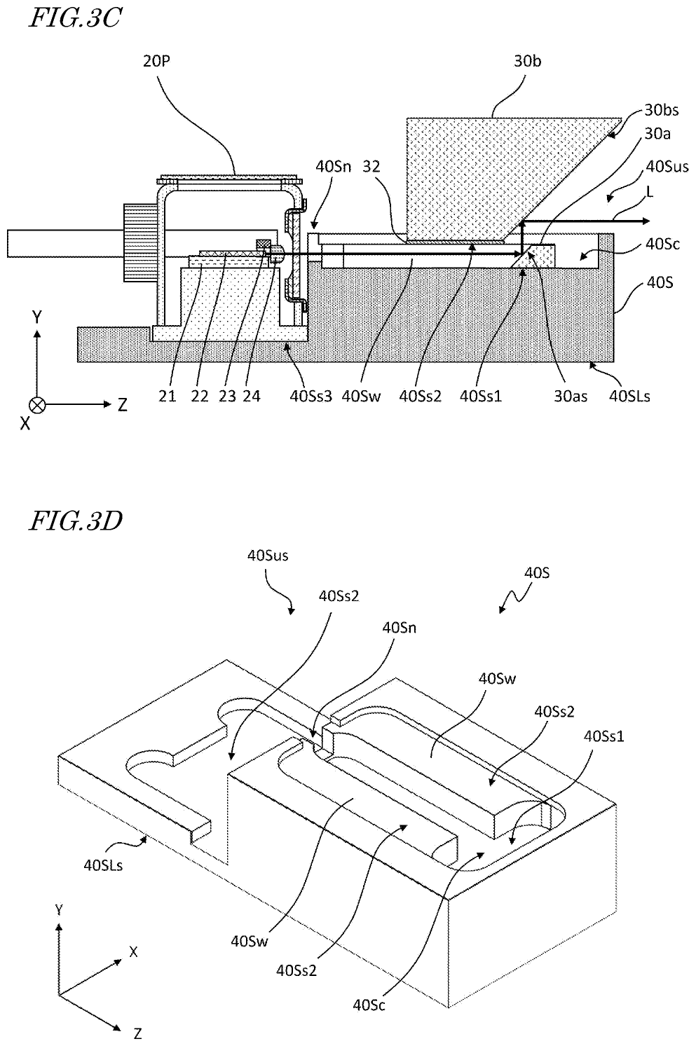

A configuration example of a light-emitting device according to a second embodiment of the present disclosure will be described below with reference to FIG. 3A to FIG. 3D. In the light-emitting module 200 illustrated in FIG. 1A to FIG. 1C, the light-emitting device according to the second embodiment may be used instead of the light-emitting device 100A according to the first embodiment. In the light-emitting device according to the second embodiment, the semiconductor laser element 22 is sealed by a package, the first mirror member 30a is positioned outside a space in which the semiconductor laser element 22 is sealed, and the second mirror member 30b is positioned outside the space.

FIG. 3A is a perspective view schematically illustrating an example of a configuration of the light-emitting device according to the exemplary second embodiment of the present disclosure. FIG. 3B is a perspective view schematically illustrating another example of the configuration of the light-emitting device according to the exemplary second embodiment of the present disclosure. A light-emitting device 100B illustrated in FIG. 3A and FIG. 3B includes a laser light source 20P, the first mirror member 30a, the second mirror member 30b, and a support 40S that supports these components. FIG. 3C is a cross-sectional view parallel to a YZ plane of the light-emitting device 100B illustrated in FIG. 3B. FIG. 3D is a perspective view schematically illustrating a configuration of the support 40S included in the light-emitting device 100B illustrated in FIG. 3A and FIG. 3B. The support 40S includes a first support surface 40Ss1 that supports the first mirror member 30a, a second support surface 40Ss2 that supports the second mirror member 30b, and a third support surface 40Ss3 that supports the laser light source 20P.

The laser light source 20P emits the laser beams L in substantially the +Z direction. The traveling direction of the laser beams L emitted from the laser light source 20P may not be completely parallel to the +Z direction which is the designed traveling direction. As will be described in detail below, in the light-emitting device 100B according to the second embodiment, regardless of whether the traveling direction of the laser beams L emitted from the laser light source 20P deviates from the +Z direction, as illustrated in FIG. 3C, the traveling direction of the laser beams L can be directed to the +Z direction which is the designed traveling direction, as a result of the laser beams L emitted from the laser light source 20P being reflected by the first reflective surface 30as and the second reflective surface 30bs in this order.

Furthermore, in the light-emitting device 100B according to the second embodiment, as illustrated in FIG. 3A and FIG. 3B, as the second reflective surface 30bs of the second mirror member 30b is shifted along the +Z direction, the height of the optical axis of the laser beams L reflected by the second reflective surface 30bs decreases. Therefore, even disposing the plurality of light-emitting devices 100B on the same plane allows the heights of the optical axes of the laser beams emitted from the plurality of light-emitting devices 100B to be made different from each other.

Each of components of the light-emitting device 100B will be described below.

Laser Light Source 20P

As illustrated in FIG. 3C, the laser light source 20P includes the submount 21, the semiconductor laser element 22, the lens support member 23, the fast-axis collimating lens 24, and a package sealing these components. The configuration including the submount 21, the semiconductor laser element 22, the lens support member 23, and the fast-axis collimating lens 24 is as described in the first embodiment. The laser light source 20P emits, in substantially the +Z direction, the laser beams L emitted from the semiconductor laser element 22 and collimated in the YZ plane by the fast-axis collimating lens 24. A specific configuration of the laser light source 20P will be described below.

The traveling direction of the laser beams L emitted from the laser light source 20P may actually deviate from the +Z direction. An angle formed between the traveling direction of the laser beams L emitted from the laser light source 20P and the +Z direction may be 10° or less, for example.

First Mirror Member 30a and Second Mirror Member 30b

The first mirror member 30a and the second mirror member 30b are as described in the light-emitting device 100A according to the first embodiment. However, in the light-emitting device 100B according to the second embodiment, the cross-sectional shape of the first mirror member 30a is not substantially triangular but substantially trapezoidal.

As illustrated FIG. 3C, the first reflective surface 30as reflects the laser beams L emitted from the laser light source 20P to change the traveling direction of the laser beams L to the direction away from a first support surface 40S1 of the support 40S. It can also be said that the first reflective surface 30as reflects the laser beams L and changes the traveling direction of the laser beams L to a direction moving away from the first placement surfaces 60s1 illustrated in FIG. 1A to FIG. 1C. An angle formed between the direction in which the laser beams L move away from the first support surface 40S1 of the support 40S or the first placement surfaces 60s1 and the normal direction of the mounting surface 10us may be in a range from 0° to 5°, for example. Because this angle has a tolerance of 5°, it is not necessary to adjust the position and orientation of the first mirror member 30a with as much precision as the position and orientation of the second mirror member 30b.

The second reflective surface 30bs is provided on the inclined surface of the second mirror member 30b. At least a portion of the second reflective surface 30bs is positioned above at least a portion of the first reflective surface 30as. As illustrated in FIG. 3C, the second reflective surface 30bs reflects the laser beams L reflected by the first reflective surface 30as to change the traveling direction of the laser beams L to the +Z direction. The adjustment of the position and orientation of the second mirror member 30b will be described below.

As illustrated in FIG. 3A and FIG. 3B, as the second mirror member 30b is shifted in the +Z direction and approaches the first mirror member 30a, the height of the optical axis of the laser beams L reflected by the second reflective surface 30bs decreases. As described in the first embodiment, the greater the size from the upper edge to the lower edge of the second reflective surface 30bs, the more widely the range over which the height of the optical axis of the laser beams L reflected by the second reflective surface 30bs can be adjusted.

Here, unlike the second embodiment, even disposing the wedge described in the first embodiment instead of the first mirror member 30a and the second mirror member 30b allows the traveling direction of the laser beams L emitted from the laser light source 20P to be directed to the +Z direction. However, when using the wedge, to direct the traveling direction of the laser beams L to the +Z direction, it is necessary to prepare a plurality of the wedges for which the normal directions of the light-emitting surfaces are mutually different to select the wedge having the appropriate normal direction of the light-emitting surface from among the plurality of wedges.

In contrast, in the second embodiment, disposing the second mirror member 30b in an appropriate position and orientation allows the traveling direction of the laser beams L emitted from the laser light source 20P to be directed to the +Z direction. Thus, it is not necessary to prepare a plurality of the second mirror members 30b having mutually different angles between the upper surface and the inclined surface to select the second mirror member having the appropriate angle from among the plurality of second mirror members 30b.

Support 40S

As illustrated in FIG. 3C and FIG. 3D, the support 40S has an upper surface 40Sus having protrusions and recessions and a lower surface 40SLs that is a plane parallel to the XZ plane.

The support 40S includes a recess 40Sc in the upper surface 40Sus. The support 40S includes, in the recess 40Sc, a cutout portion 40Sn through which the laser beams L emitted from the laser light source 20P pass. The support 40S further includes, in the recess 40Sc, two wall portions 40Sw positioned on both sides of the optical path of the laser beams L emitted from the laser light source 20P.

The support 40S has, in the upper surface 40Sus, the first support surface 40Ss1 which is at least a part of the bottom surface of the recess 40Sc. The first support surface 40Ss1 is parallel to the XZ plane. The first support surface 40Ss1 supports the first mirror member 30a so that the first reflective surface 30as reflects the laser beams L to change the traveling direction of the laser beams L to the direction away from the support 40s. A part of the first mirror member 30a is positioned between the two wall portions 40Sw. The lower surface of the first mirror member 30a is bonded to the first support surface 40Ss1. A resin layer for bonding is provided between the first support surface 40Ss1 and the lower surface of the first mirror member 30a. A thickness (a size in the Y direction) of the resin layer may be in a range from 0.005 mm to 0.5 mm, for example. Heat generated in the first mirror member 30a by the irradiation of the laser beams L during driving can be effectively transmitted to the support 40S via the first support surface 40Ss1 supporting the first mirror member 30a. As long as the thickness (the size in the Y direction) of the resin layer is within the above-described range, the resin layer does not significantly hinder the heat transfer to the support 40S. The same applies to a resin layer described below.

The support 40S has a second support surface 40Ss2, which is at least a part of the upper surfaces of the two wall portions 40Sw in the upper surface 40Sus. The second support surface 40Ss2 is parallel to the XZ plane. The second support surface 40Ss2 supports the second mirror member 30b so that least a portion of the second reflective surface 30bs is positioned above at least a portion of the first reflective surface 30as. The second support surface 40Ss2 further supports the second mirror member 30b so that the second reflective surface 30bs reflects the laser beams L reflected by the first reflective surface 30as to change the traveling direction of the laser beams L to the +Z direction. In the example illustrated in FIG. 3C, the second support surface 40Ss2 supports both ends of the second mirror member 30b. When the recess 40Sc includes only one of the wall portions 40Sw instead of the two wall portions 40Sw, the second support surface 40Ss2 supports one end of the second mirror member 30b. A portion of the lower surface of the second mirror member 30b, more specifically, the lower surface of one end or both ends of the second mirror member 30b, is bonded to the second support surface 40Ss2. A resin layer 32 for bonding is provided between the second support surface 40Ss2 and the portion of the lower surface of the second mirror member 30b. The portion of the lower surface of the second mirror member 30b is brought into contact with the second support surface 40Ss2 via the uncured resin, and the second mirror member 30bs is adjusted to an appropriate position and orientation so that the second reflective surface 30b changes the traveling direction of the laser beams L to the +Z direction. When adjusting the position and orientation of the second mirror member 30b, the active alignment described in the first embodiment is performed. Subsequently, the resin is cured to form the resin layer 32. The adjustment of the position and orientation of the second mirror member 30b may be performed while holding the second mirror member 30b using a holding device, after the light-emitting device 100B is disposed on the first placement surface 60s1 of the support base 60A illustrated in FIG. 1A to FIG. 1C. Heat generated in the second mirror member 30b by the irradiation of the laser beams L during driving can be effectively transmitted to the support 40S via the second support surface 40Ss2 supporting the second mirror member 30b.

When viewed from the support 40S, a plane parallel to the XZ plane positioned on the side opposite to the surface on which the first mirror member 30a and the second mirror member are mounted is defined as a reference plane for the height of the light-emitting device 100B. The reference plane can be, for example, the lower surface 40SLs of the support 40S illustrated in FIG. 3C and FIG. 3D. The “height” described below is a height from the reference plane. The height of the second support surface 40Ss2 is greater than the height of the first support surface 40Ss1. The second mirror member 30b supported by the second support surface 40Ss2 is positioned above the optical path of the laser beams L emitted from the laser light source 20P and does not obstruct the travel of the laser beams L.

Unlike the light-emitting device 100B according to the second embodiment, in a configuration in which the height of the second support surface 40Ss2 is equal to the height of the first support surface 40Ss1, the second mirror member 30b is required to have a complicated shape across the optical path of the laser beams L so as not to obstruct the travel of the laser beams L emitted from the laser light source 20P. In contrast, in the light-emitting device 100B according to the second embodiment, because the height of the second support surface 40Ss2 is greater than the height of the first support surface 40Ss1, the second mirror member 30b does not need to have such a complicated shape. The second mirror member 30b may have a simple shape with a flat lower surface.

The first support surface 40Ss1 and the second support surface 40Ss2 are flat surfaces parallel to each other. Therefore, when the angle formed between the upper surface and the inclined surface of the second mirror member 30b is equal to the angle formed between the lower surface and the inclined surface of the first mirror member 30a, when the portion of the lower surface of the second mirror member 30b is brought into contact with the second support surface 40Ss2 via the uncured resin, the second reflective surface 30bs becomes substantially parallel to the first reflective surface 30as. Because the position and orientation of the second mirror member 30b can be finely adjusted from this state, the second mirror member 30b can be easily disposed at an appropriate position and with an appropriate orientation.

The first reflective surface 30as and the second reflective surface 30bs are positioned away from each other, and a gas such as air is provided between the first reflective surface 30as and the second reflective surface 30bs. Because, while traveling from the first reflective surface 30as to the second reflective surface 30bs, the laser beams L are not incident on the resin layer 32 between the second mirror member 30b and the second support surface 40Ss2, it is possible to reduce a deterioration of the resin layer 32. The distance in the Z direction from the first reflective surface 30as to the second reflective surface 30bs can be in a range from 0.1 mm to 3 mm, for example.

The size of the second reflective surface 30bs in the X direction is larger than a maximum interval between the two wall portions 40Sw, and the size of the first reflective surface 30as in the X direction is smaller than the maximum interval. Thus, the size of the second reflective surface 30bs in the X direction is larger than the size of the first reflective surface 30as in the X direction. For example, the size of the second reflective surface 30bs in the X direction can be in a range from 1.1 times to 4 times the size of the first reflective surface 30as in the X direction. Because the second reflective surface 30bs has such a size, the second reflective surface 30bs is likely to receive the laser beams L whose width in the X direction increases while traveling from the first reflective surface 30as to the second reflective surface 30bs.

Some of the laser beams L reflected by the first reflective surface 30as and/or the second reflective surface 30bs may become stray light, and the stray light may spread as the laser beams L travel. Even in this case, as long as the interval between the two wall portions 40Sw in the X direction is narrow, it is possible to reduce the incidence of the stray light on the laser light source 20P as return light. The distance between the two wall portions 40Sw in the X direction can be in a range from 0.1 mm to 3 mm, for example. As long as the interval is within this range, it is possible to appropriately reduce the incidence of the stray light on the laser light source 20P as the return light. Furthermore, when the height (the size in the Y direction) of the wall portion 40Sw is large, it is possible to inhibit stray light generated at the first reflective surface 30as from being incident on the resin layer 32 present between the second mirror member 30b and the second support surface 40Ss2, and thus reduce the deterioration of the resin layer 32. The height of the wall portion 40Sw can be in a range from 0.1 mm to 5 mm, for example. As long as the height is within this range, it is possible to effectively inhibit such stray light from being incident on the resin layer. Because the stray light generated at the second reflective surface 30bs often travels in a direction away from the resin layer, the possibility that such stray light is incident on the resin layer 32 is low.

The support 40S further includes a third support surface 40Ss3 positioned on the outside of the recess 40Sc in the upper surface 40Sus. The third support surface 40Ss3 is parallel to the XZ plane. The third support surface 40Ss3 supports the laser light source 20P. An inorganic bonding layer for bonding is provided between the third support surface 40Ss3 and the lower surface of the laser light source 20P. Heat generated in the laser light source 20P during driving can be effectively transmitted to the support 40S via the third support surface 40Ss3. Because the height of the third support surface 40Ss3 is smaller than the height of the first support surface 40Ss1, the laser light source 20P supported by the third support surface 40Ss3 easily causes the laser beams L to be incident on the first reflective surface 30as.

The support 40 can be formed of the same material as the support base 60A illustrated in FIG. 1A to FIG. 1C, for example. In this case, the support 40S can effectively transmit the heat generated from the laser light source 20P during driving, and the heat generated in the first mirror member 30a and the second mirror member 30b by the irradiation of the laser beams L to the support base 60A. The support 40S may be integrally formed with the support base 60A. In this case, the support 40S corresponds to a part of the support base 60A.

As described above, the second embodiment can implement the light-emitting device 100A that can reduce the deviation between the traveling direction of the laser beams L and the designed traveling direction. Furthermore, even disposing the plurality of light-emitting devices 100B on the same plane allows the heights of the optical axes of the laser beams L emitted from the plurality of light-emitting devices 30b to be made different from each other by making the positions of the second reflective surfaces 30bs of the plurality of second mirror members 100B in the Z direction different from each other. The height of the intersection point of the second reflective surface 30bs and the optical axis of the laser beams L with respect to the above-described same plane differs depending on the position of the second reflective surface 30b of the plurality of second mirror members 30bs in the +Z direction. Employing this type of the light-emitting device 100B in the light-emitting module 200 illustrated in FIG. 1A to FIG. 1C allows the plurality of laser beams L obtained from the laser beams L emitted from each of the plurality of light-emitting devices 100B to be effectively combined and caused to be incident on the optical fiber 80.

The light-emitting device 100B may be manufactured in the following manner. In an initial step, the laser light source 20P, the first mirror member 30a, the second mirror member 30b, and the support 40S are prepared. In a subsequent step, the laser light source 20P is bonded to the third support surface 40Ss3 of the support 40S. In a subsequent step, the first mirror member 30a is bonded to the first support surface 40Ss1 of the support 40S. In a subsequent step, active alignment is performed with the lower surface of the second mirror member 30b in contact with the second support surface 40Ss2 of the support 40S via the uncured resin. In a subsequent step, the resin is cured and the resin layer 32 is formed between the second mirror member 30b and the support 40.

### Third Embodiment

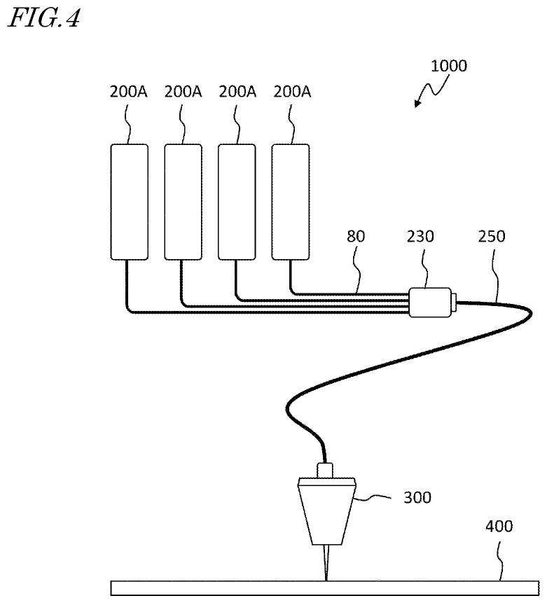

Next, with reference to FIG. 4, a configuration example of a DDL device according to a third embodiment of the present disclosure will be described. FIG. 4 is a top view schematically illustrating a configuration of the DDL device according to the exemplary third embodiment of the present disclosure. A DDL device 1000 illustrated in FIG. 4 includes the plurality of light-emitting modules 200 according to the first embodiment, a processing head 300, and an optical transmission fiber 250 connecting the light-emitting modules 200 to the processing head 300. In the example illustrated in FIG. 4, the number of the light-emitting modules 200 is four, but the configuration is not limited to this number. The number of the light-emitting modules 200 may be one or may be two, three, or five or more.

The number of the light-emitting devices 100A included in each of the light-emitting modules 200 is determined according to the required light output or irradiance. The wavelength of the laser beams emitted from the light-emitting device 100A may also be selected in accordance with the material to be processed. In processing, for example, a metal such as copper, brass, or aluminum, the semiconductor laser element having a center wavelength in a range from 350 nm to 550 nm may be favorably employed. The wavelengths of the laser beams emitted from each of the light-emitting devices 100A do not need to be the same, and laser beams having different center wavelengths may be superimposed. The effects according to the present invention can also be obtained in using laser beams having a center wavelength outside the range from 350 nm to 550 nm.

In the example illustrated in FIG. 4, the optical fiber 80 extends from each of the plurality of light-emitting modules 200. The plurality of optical fibers 80 thus obtained is connected to the optical transmission fiber 250 by an optical multiplexer 230. The optical multiplexer 230 may be, for example, a tapered fiber bundle (TFB). The processing head 300 converges and irradiates the laser beams emitted from the light-emitting end of the optical fibers 80 onto an object 400. When the one DDL device 1000 includes M of the light-emitting modules 200 and each of the light-emitting modules 200 includes N of the light-emitting devices 100, if the light output of the one light-emitting device 100A is P watts, a laser beam having a maximum light output of P×N×M watts can be focused on the target 400. Here, N is an integer of 2 or more, and M is a positive integer. For example, if P is 20 watts, N is 22, and M is 12, a light output in excess of 5 kilowatts can be achieved.

Configuration of Laser Light Source 20

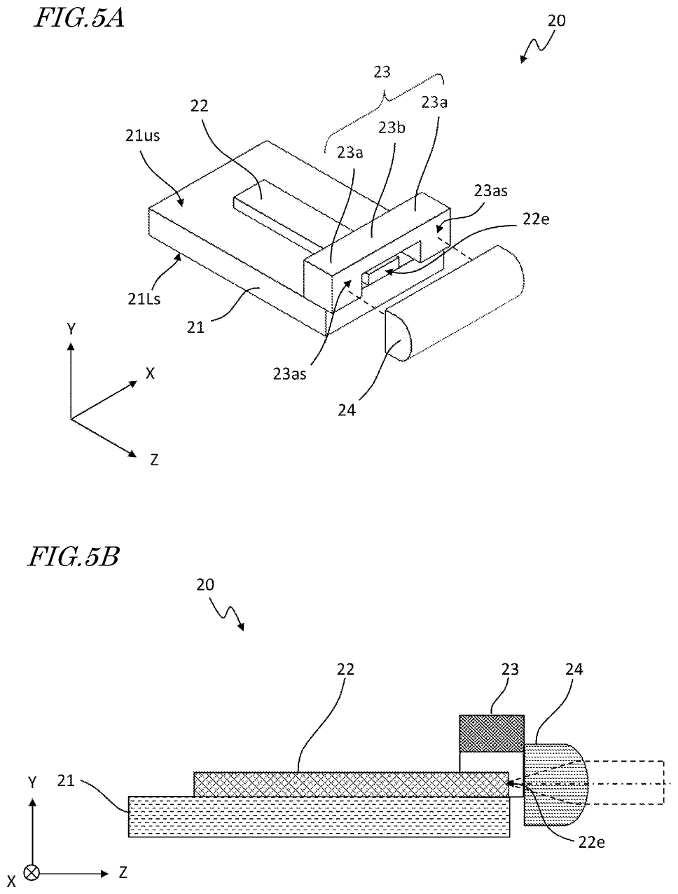

Next, with reference to FIG. 5A and FIG. 5B, an example of a configuration of the laser light source 20 included in the light-emitting device 100A according to the first embodiment will be described. FIG. 5A is an exploded perspective view schematically illustrating an example of the configuration of the laser light source included in the light-emitting device 100A according to the first embodiment. FIG. 5B is a cross-sectional view parallel to the YZ plane of the laser light source 20. Each of the components of the laser light source 20 will be described below.

As illustrated in FIG. 5A, the submount 21 has an upper surface 21us and a lower surface 21Ls that are parallel to the XZ plane. A metal film is provided on each of the upper surface 21us and the lower surface 21Ls. The metal film provided on the upper surface 21us improves the bonding strength when the semiconductor laser element 22 and the lens support member 23 are bonded to the submount 21 by an inorganic bonding member. The metal film provided on the upper surface 21us may be further used to supply electric power to the semiconductor laser element 22. The metal film provided on the lower surface 21Ls improves the bonding strength when the substrate 10 and the laser light source 20 illustrated in FIG. 2C are bonded to each other via the inorganic bonding member. The metal films provided on each of the upper surface 21us and the lower surface 21Ls also serve to transfer heat generated by the semiconductor laser element 22 during driving to the substrate 10, via the submount 21. Similar to, for example, the support base 60A illustrated in FIG. 1A to FIG. 1C, the submount 21 can be formed of the above-described ceramics, metal material, or metal-matrix composite material.

As illustrated in FIG. 5A, the semiconductor laser element 22 is supported by the upper surface 21us of the submount 21. The semiconductor laser element 22 has an emission surface 22e on one of two end surfaces intersecting the Z direction, and emits the laser beams from the emission surface 22e in the +Z direction. The laser beams spread at different speeds in the YZ plane and the XZ plane as they travel in the +Z direction. The laser beams spread relatively fast in the YZ plane and spread relatively slowly in the XZ plane. When the laser beams are not collimated, in the far field, the spot of the laser beams has an elliptical shape in which the Y direction is the long axis and the X direction is the short axis in the XY plane.

The semiconductor laser element 22 can emit violet, blue, green, or red laser light in the visible region, or infrared or ultraviolet laser light in the invisible region. The light emission peak wavelength of the violet light is preferably in a range from 400 nm to 420 nm, and more preferably in a range from 400 nm to 415 nm. The light emission peak wavelength of the blue light is preferably in a range from 420 nm to 495 nm, and more preferably in a range from 440 nm to 475 nm. The light emission peak wavelength of the green light is preferably in a range from 495 nm to 570 nm, and more preferably in a range from 510 nm to 550 nm. The light emission peak wavelength of the red light is preferably in a range from 605 nm to 750 nm, and more preferably in a range from 610 nm to 700 nm.

Examples of the semiconductor laser element 22 that emits the violet light, blue light, and the green light include a laser diode including a nitride semiconductor material. For example, GaN, InGaN, and AlGaN can be used as the nitride semiconductor material. Examples of the semiconductor laser element 22 that emits the red light include a laser diode including an InAlGaP-based, a GaInP-based, a GaAs-based, and a AlGaAs-based semiconductor material.

As illustrated in FIG. 5A, the lens support member 23 is supported by the upper surface 21us of the submount 21. The lens support member 23 includes two columnar portions 23a and a link portion 23b that is positioned between the two columnar portions 23a and links the two columnar portions 23b. The two columnar portions 23a are positioned on both sides of the semiconductor laser element 22, and the link portion 23b is positioned above the emission surface 22e side of the semiconductor laser element 22. The lens support member 23 supports the fast-axis collimating lens 24 using end surfaces 23as of the two columnar portions 23a. The lens support member 23 is positioned straddling the semiconductor laser element 22 and does not obstruct the laser beams emitted from the semiconductor laser element 22 from being incident on the fast-axis collimating lens 24.

Similar to, for example, the support base 60A illustrated in FIG. 1A to FIG. 1C, the lens support member 23 may be formed of the above-described ceramics. Similar to, for example, the condensing lens 70 illustrated in FIG. 1A to FIG. 1C, the lens support member 23 may be formed of the above-described light-transmissive material. The lens support member 23 may be formed of at least one alloy selected from the group consisting of Kovar and CuW, for example. Kovar is an alloy in which nickel and cobalt are added to iron as a main component.

The lens support member 23 may be formed of Si, for example.

As illustrated in FIG. 5A, the fast-axis collimating lens 24 may be, for example, a cylindrical lens having a uniform cross-sectional shape in the X direction. The fast-axis collimating lens 24 has a flat surface on a light incident side and a convex curved surface on a light emitting side. The convex curved surface has a curvature in the YZ plane. The focal point of the fast-axis collimating lens 24 substantially coincides with a center of a light emission point of the emission surface 22e of the semiconductor laser element 22. As illustrated in FIG. 5B, the fast-axis collimating lens 24 collimates the laser beams emitted in the +Z direction from the emission surface 22e of the semiconductor laser element 22, in the YZ plane. A region surrounded by a broken line illustrated in FIG. 5B represents a region in which the intensity of the laser beams is 1/e 2 times or more of the peak intensity, where “e” is the base of a natural logarithm. Similar to, for example, the condensing lens 70 illustrated in FIG. 1A to FIG. 1C, the fast-axis collimating lens 24 may be formed of the above-described light-transmissive material.

As illustrated in FIG. 2G, the fast-axis collimating lens 24 is positioned between the mounting surface 10us of the substrate 10 and the lower surface 50Ls of the cover 50, and is positioned on the optical path of the laser beams L. Because the fast-axis collimating lens 24 is disposed inside the sealed space formed by the substrate 10, the frame body 40, and the cover 50, the laser beams L can be collimated before the laser beams L spread significantly. Therefore, the size of the fast-axis collimating lens 24 can be reduced.

Instead of the fast-axis collimating lens 24, a collimating lens may be used that collimates the laser beams L emitted from the semiconductor laser element 22 not only in the YZ plane but also in the XZ plane. In this case, it is not necessary to provide the slow-axis collimating lenses 92, 92a, and 92b in the light-emitting module 200 illustrated in FIG. 1A to FIG. 1C and the light-emitting module 210 illustrated in FIG. 1D.

Configuration of Laser Light Source 20P

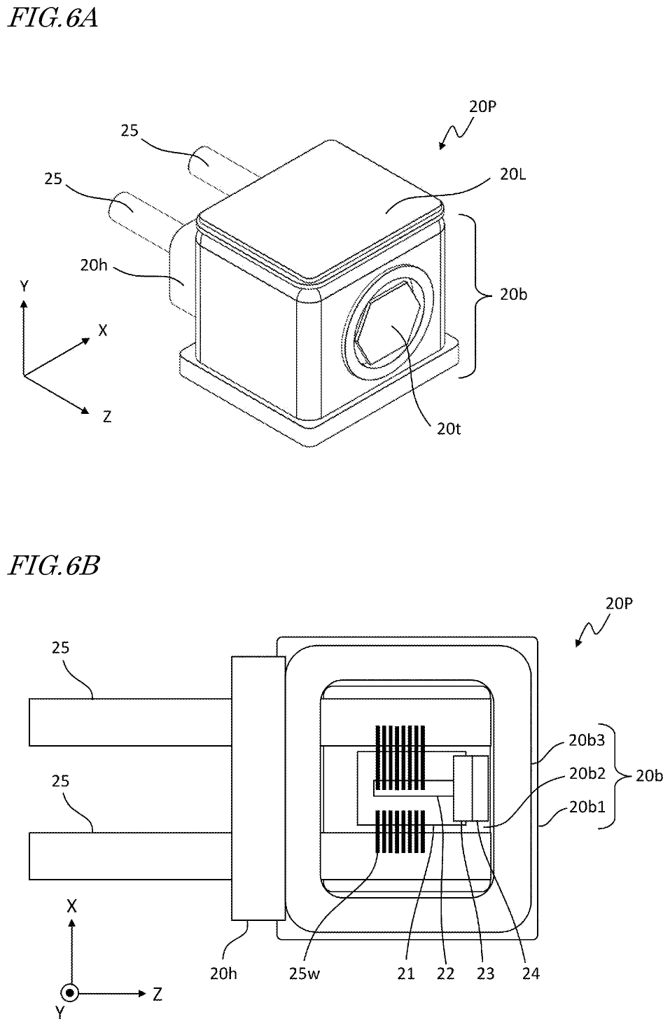

Next, an example of a configuration of the laser light source 20P included in the light-emitting device 100B according to the second embodiment will be described with reference to FIG. 6A and FIG. 6B. FIG. 6A is a perspective view schematically illustrating a configuration example of the laser light source 20P included in the light-emitting device 100B according to the second embodiment. The laser light source 20P illustrated in FIG. 6A includes the submount 21 illustrated in FIG. 5A, the semiconductor laser element 22, the lens support member 23, the fast-axis collimating lens 24, and a base member 20b storing these components. The base member 20b includes a light-transmitting window 20t that transmits the laser beams L emitted from the semiconductor laser element 22. The laser light source 20P further includes two lead terminals 25 that supply electric power to the laser light source 20P, a lead holding member 20h that holds the two lead terminals 25, and a lid 20L fixed to the base member 20b. The lid 20L forms a sealed space that seals the semiconductor laser element 22, together with the base member 20b, the lead holding member 20h, and the two lead terminals 25. As described in the first embodiment, this seal is preferably a hermetic seal. In the present description, a configuration including the base member 20b, the lead holding member 20h, the two lead terminals 25, and the lid 20L is also referred to as a “package.”

FIG. 6B is a view schematically illustrating a planar configuration of the interior of the laser light source 20P illustrated in FIG. 6A. In FIG. 6B, the lid 20L illustrated in FIG. 6A is omitted. The base member 20b includes a bottom plate 20b1, a stage 20b2 provided on the bottom plate 20b1, and a side wall 20b3 surrounding the stage 20b2. The light-transmitting window 20t illustrated FIG. 6A is provided in the side wall 20b3. It can also be said that the side wall 20b3 includes the light-transmitting window 20t illustrated in FIG. 6A. The laser light source 20P includes the submount 21 supported by the stage 20b2, the semiconductor laser element 22 and the lens support member 23 supported by the submount 21, and the fast-axis collimating lens 24 supported by lens support member 23. The semiconductor laser element 22 is supported by the support 40S illustrated in FIG. 3A and FIG. 3B, via the bottom plate 20b1, the stage 20b2, and the submount 21. The configuration including the submount 21, the semiconductor laser element 22, the lens support member 23, and the fast-axis collimating lens 24 is as described with reference to FIG. 5A and FIG. 5B.

Of the base member 20b, the bottom plate 20b1 and the stage 20b2 may be formed of a metal material including at least one metal selected from the group consisting of Cu, Al, Ag, Fe, Ni, Mo, and Cu, for example. Other examples of metal materials include alloys, such as CuMo. Because the bottom plate 20b1 and the stage 20b2 formed of such a metal material, including alloys, have a high thermal conductivity, heat generated from the semiconductor laser element 22 during driving can be effectively transmitted to the outside. Of the base member 20b, the side wall 20b3 may be formed of Kovar, for example.

The laser light source 20P further includes a plurality of wires 25w in the interior of the base member 20b. Among the plurality of wires 25w, some of the wires 25w are electrically connected to the semiconductor laser element 22 via the submount 21 and are also electrically connected to one of the lead terminals 25. The remaining wires 25w are electrically connected directly to the semiconductor laser element 22 and are also electrically connected to the other lead terminal 25. The plurality of wires 25w is used to supply the electric power from the two lead terminals 25 to the semiconductor laser element 22. The two lead terminals 25 are electrically connected to an external circuit that adjusts an emission timing and output of the laser beams emitted from the semiconductor laser element 22.

The laser light source 20P is disclosed in more detail in JP 2021-106247 A, for example. The entire disclosure of JP 2021-106247 A is incorporated herein by reference.

The present disclosure includes a light-emitting module described in the following aspects.

Aspect 1

A light-emitting module, including:
a support base having a plurality of placement surfaces arranged in a first direction;
a plurality of semiconductor laser elements disposed on the corresponding respective plurality of placement surfaces and each configured to emit laser beams;
a plurality of first mirror members each having a first reflective surface, the first reflective surface reflecting the laser beams to change a traveling direction of the laser beams; and
a plurality of second mirror members each having a second reflective surface, at least a portion of the second reflective surface being positioned above at least a portion of the first reflective surface, and the second reflective surface reflecting, in a second direction intersecting the first direction, the laser beams reflected by the first reflective surface, wherein
positions of the second reflective surfaces of the plurality of second mirror members in the second direction are different from each other.

Aspect 2

The light-emitting module according to aspect 1, further including:
a plurality of third mirror members each having a third reflective surface, the third reflective surface reflecting, in the first direction, the laser beams reflected by the second reflective surface; and
a condensing lens configured to converge, onto an optical fiber, a plurality of laser beams obtained from the laser beams reflected on the third reflective surface of each of the plurality of third mirror members.

Aspect 3

The light-emitting module according to aspect 1 or 2, wherein the positions of the second reflective surfaces of the plurality of second mirror members in the second direction are different from each other along the first direction in a stepwise manner in the second direction.

Aspect 4

The light-emitting module according to any one of aspects 1 to 3, wherein the first reflective surface reflects the laser beams to change the traveling direction of the laser beams to a direction away from each of the placement surfaces.

Aspect 5

The light-emitting module according to any one of aspects 1 to 4, wherein the plurality of placement surfaces is positioned on a same plane.

Aspect 6

The light-emitting module according to aspect 5, wherein the second direction is parallel to the same plane.

Aspect 7

The light-emitting module according to aspect 5, wherein a height of an intersection point of the second reflective surface and an optical axis of the laser beams with respect to the same plane differs depending on the position of the second reflective surface of each of the plurality of second mirror members in the second direction.

Aspect 8

The light-emitting module according to any one of aspects 1 to 7, wherein
each of the semiconductor laser elements is sealed,
a corresponding first mirror member is positioned inside a space in which each of the semiconductor laser elements is sealed, and
a corresponding second mirror member is positioned outside the space.

Aspect 9

The light-emitting module according to any one of aspects 1 to 7, wherein
each of the semiconductor laser elements is sealed,
a corresponding first mirror member is positioned outside a space in which each of the semiconductor laser elements is sealed, and
a corresponding second mirror member is positioned outside the space.

### INDUSTRIAL APPLICABILITY

A light-emitting device according to the present disclosure may be particularly used for combining a plurality of laser beams to achieve high-power laser light. Further, the light-emitting device according to the present disclosure may be used for industrial fields requiring a high-power laser light source, such as cutting, drilling, local heat treatment, surface treatment, metal welding, and 3D printing of various materials.

### REFERENCE CHARACTER LIST

10 Substrate
10us Mounting surface
10Ls Lower surface
20P Laser light source
20b Base member
20b1 Bottom plate
20b2 Stage
20b3 Side wall
20h Lead holding member
20t Light-transmitting window
21 Submount
21Ls Lower surface
21us Upper surface
22 Semiconductor laser element
22e Emission surface
23 Lens support member
23a Columnar portion
23as End surface
23b Link portion
24 Fast-axis collimating lens
25 Lead terminal
25w Wire
30a First mirror member
30as First reflective surface
30b Second mirror member
30bs Second reflective surface
32 Resin layer
40 Frame body
40us1 First upper surface
40us2 Second upper surface
40Ls1 First lower surface
40Ls2 Second lower surface
40p Protruding portion
40w Wire
42a First conductive region
42b Second conductive region
42c Third conductive region
42d Fourth conductive region
44a First bonding region
44b Second bonding region
44c Third bonding region
46 Outer region
40S Support
40Sc Recess
40Sn Cutout portion
40Ss1 First support surface
40Ss2 Second support surface
40Ss3 Third support surface
40Sus Upper surface
40SLs Lower surface
40Sw Wall portion
50 Cover
50us Upper surface
50Ls Lower surface
50t Light-transmitting region
52 Light-shielding film
60A, 62A Support base
60A1, 62A1 First portion
60A2, 62A2 Second portion
60A3, 62A3 Third portion
60s1 First placement surface
60s2 Second placement surface
60s3 Third placement surface
70 Condensing lens
70a Fast-axis condensing lens
70b Slow-axis condensing lens
80 Optical fiber
80a Light-incident end
80b Light-emitting end
82 Support member
92 Slow-axis collimating lens
92a Slow-axis collimating lens
92b Slow-axis collimating lens
94, 94a, 94b, 94c Mirror member
94s, 94as, 94bs, 94cs Reflective surface
96 Half-wave plate
98 Polarizing beam splitter
100A, 100A1, 100A2, 100B Light-emitting device
200, 210 Light-emitting module
230 Optical multiplexer
250 Optical transmission fiber
300 Processing head
400 Object
1000 DDL device

What is claimed is:

1. A light-emitting module comprising:
a support base having a plurality of placement surfaces arranged in a first direction;
a plurality of semiconductor laser elements disposed on respective ones of the plurality of placement surfaces, each semiconductor laser element configured to emit laser beams;
a plurality of first mirror members, each having a first reflective surface configured to reflect and change a traveling direction of the laser beams from a respective one of the semiconductor laser elements; and
a plurality of second mirror members, each having a second reflective surface, at least a portion of the second reflective surface being positioned above at least a portion of a respective one of the first reflective surfaces, and the second reflective surface being configured to reflect, in a second direction intersecting the first direction, the laser beams reflected by the respective first reflective surface, wherein:
positions of the second reflective surfaces of the plurality of second mirror members in the second direction are different from each other.

2. The light-emitting module according to claim 1, further comprising:
a plurality of third mirror members, each having a third reflective surface configured to reflect, in the first direction, the laser beams reflected by a respective one of the second reflective surfaces; and
a condensing lens configured to converge, onto an optical fiber, a plurality of laser beams obtained from the laser beams reflected on the third reflective surface of each of the plurality of third mirror members.

3. The light-emitting module according to claim 1, wherein the positions of the second reflective surfaces of the plurality of second mirror members in the second direction are different from each other along the first direction in a stepwise manner in the second direction.

4. The light-emitting module according to claim 2, wherein the positions of the second reflective surfaces of the plurality of second mirror members in the second direction are different from each other along the first direction in a stepwise manner in the second direction.

5. The light-emitting module according to claim 1, wherein the first reflective surface is configured to reflect the laser beams to change the traveling direction of the laser beams to a direction away from each of the placement surfaces.

6. The light-emitting module according to claim 2, wherein the first reflective surface is configured to reflect the laser beams to change the traveling direction of the laser beams to a direction away from each of the placement surfaces.

7. The light-emitting module according to claim 1, wherein the plurality of placement surfaces are positioned on a same plane.

8. The light-emitting module according to claim 2, wherein the plurality of placement surfaces are positioned on a same plane.

9. The light-emitting module according to claim 7, wherein the second direction is parallel to said plane.

10. The light-emitting module according to claim 8, wherein the second direction is parallel to said plane.

11. The light-emitting module according to claim 7, wherein a height of an intersection point of the second reflective surface and an optical axis of the laser beams with respect to said plane differs depending on the position of the second reflective surface of each of the plurality of second mirror members in the second direction.

12. The light-emitting module according to claim 8, wherein a height of an intersection point of the second reflective surface and an optical axis of the laser beams with respect to said plane differs depending on the position of the second reflective surface of each of the plurality of second mirror members in the second direction.

13. The light-emitting module according to claim 1, wherein:
each of the semiconductor laser elements is sealed;
each first mirror member is positioned inside a space in which a respective one of the semiconductor laser elements is sealed; and
each second mirror member is positioned outside the space in which the respective one of the semiconductor laser elements is sealed.

14. The light-emitting module according to claim 2, wherein:
each of the semiconductor laser elements is sealed;
each first mirror member is positioned inside a space in which a respective one of the semiconductor laser elements is sealed; and
each second mirror member is positioned outside the space in which the respective one of the semiconductor laser elements is sealed.

15. The light-emitting module according to claim 1, wherein:
each of the semiconductor laser elements is sealed;
each first mirror member is positioned outside a space in which each of the semiconductor laser elements is sealed; and
each second mirror member is positioned outside the space in which each of the semiconductor laser elements is sealed.

16. The light-emitting module according to claim 2, wherein:
each of the semiconductor laser elements is sealed;
each first mirror member is positioned outside a space in which each of the semiconductor laser elements is sealed; and
each second mirror member is positioned outside the space in which each of the semiconductor laser elements is sealed.
